(19) United States
(12) Patent Application Publication
(10) Pub. No.: US 2026/0011635 A1
(43) Pub. Date: Jan. 8, 2026

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Myeonghoon HONG, Suwon-si (KR); Jae-Eun LEE, Suwon-si (KR)

(73) Assignee: SAMSUNG ELECTRONICS CO., LTD., Suwon-si (KR)

(21) Appl. No.: 19/022,280

(22) Filed: Jan. 15, 2025

(30) Foreign Application Priority Data
Jul. 3, 2024 (KR) 10-2024-0087439

(51) Int. Cl. H01L 23/522; H01L 23/528; H01L 25/07; H10B 41/10; H10B 41/27; H10B 41/35; H10B 43/10; H10B 43/27; H10B 43/35; H10B 80/00

(52) U.S. Cl. CPC H01L 23/5223; H01L 23/5283; H01L 25/071; H10B 41/10; H10B 41/27; H10B 41/35; H10B 43/10; H10B 43/27; H10B 43/35; H10B 80/00; H01L 2225/06506

(57) ABSTRACT

According to an aspect of the present disclosure, a semiconductor device includes a cell structure including a gate stacking structure in a first region and an insulation structure in a second region, a first wiring portion disposed on a first surface of the cell structure, a second wiring portion disposed on a second surface of the cell structure opposite to the first surface, a channel structure at least partially penetrating the gate stacking structure and being electrically coupled with the first wiring portion and the second wiring portion, and a capacitor structure including a plurality of penetration structures. The gate stacking structure includes a plurality of gate electrodes while interposing an interlayer insulation layer therebetween. Each of the plurality of penetration structures at least partially penetrates at least a portion of the insulation structure.

### CROSS-REFERENCE TO RELATED APPLICATIONS

This application claims benefit of priority under 35 U.S.C. § 119 to Korean Patent Application No. 10-2024-0087439, filed on Jul. 3, 2024, in the Korean Intellectual Property Office, the disclosure of which is incorporated by reference herein in its entirety.

### BACKGROUND

### 1. Field

The present disclosure relates to a semiconductor device and an electronic system including the same.

### 2. Description of Related Art

Semiconductor devices capable of storing high-capacity data may be in demand by, for example, electronic systems implementing a data storage. Accordingly, methods for potentially increasing data storage capacities of semiconductor devices may be being researched. For example, a possible method for potentially increasing the data storage capacity of a semiconductor device that may be proposed may relate to a semiconductor device including three-dimensionally (3D) arranged memory cells instead of two-dimensionally (2D) arranged memory cells.

### SUMMARY

One or more example embodiments of the present disclosure provide a semiconductor device capable of enhancing performance and an electronic system including the same, when compared to related semiconductor devices.

According to an aspect of the present disclosure, a semiconductor device includes a cell structure including a gate stacking structure in a first region and an insulation structure in a second region, a first wiring portion disposed on a first surface of the cell structure, a second wiring portion disposed on a second surface of the cell structure opposite to the first surface, a channel structure at least partially penetrating the gate stacking structure and being electrically coupled with the first wiring portion and the second wiring portion, and a capacitor structure including a plurality of penetration structures. The gate stacking structure includes a plurality of gate electrodes while interposing an interlayer insulation layer therebetween. Each of the plurality of penetration structures at least partially penetrates at least a portion of the insulation structure. A first one of the first wiring portion and the second wiring portion includes a capacitor wiring including a first capacitor wiring and a second capacitor wiring spaced apart from each other. The plurality of penetration structures includes a first penetration structure and a second penetration structure. The first penetration structure is electrically coupled with the first capacitor wiring and is electrically insulated from an insulated wiring portion. The insulated wiring portion is a second one of the first wiring portion and the second wiring portion. The second penetration structure is electrically coupled with the second capacitor wiring and is electrically insulated from the insulated wiring portion.

According to an aspect of the present disclosure, a semiconductor device includes a cell structure including a gate stacking structure in a first region and an insulation structure in a second region, a first wiring portion disposed on a first surface of the cell structure, a second wiring portion disposed on a second surface of the cell structure opposite to the first surface, a channel structure at least partially penetrating the gate stacking structure and being electrically coupled with the first wiring portion and the second wiring portion, and a plurality of penetration structures. The gate stacking structure includes a plurality of gate electrodes while interposing an interlayer insulation layer therebetween. Each of the plurality of penetration structures at least partially penetrates at least a portion of the insulation structure. The plurality of penetration structures includes a first penetration structure and a plurality of second penetration structures adjacent to the first penetration structure. The first penetration structure and the plurality of second penetration structures are electrically coupled with a first one of the first wiring portion and the second wiring portion. The first penetration structure and the plurality of second penetration structures are insulated from a second one of the first wiring portion and the second wiring portion.

According to an aspect of the present disclosure, an electronic system includes a main substrate, a semiconductor device disposed on the main substrate, and a controller disposed on the main substrate and electrically coupled with the semiconductor device. The semiconductor device includes a cell structure including a gate stacking structure in a first region and an insulation structure in a second region, a first wiring portion disposed on a first surface of the cell structure, a second wiring portion disposed on a second surface of the cell structure opposite to the first surface, a channel structure at least partially penetrating the gate stacking structure and being electrically coupled with the first wiring portion and the second wiring portion, and a capacitor structure including a plurality of penetration structures. The gate stacking structure includes a plurality of gate electrodes while interposing an interlayer insulation layer therebetween. Each of the plurality of penetration structures at least partially penetrates at least a portion of the insulation structure. A first one of the first wiring portion and the second wiring portion includes a capacitor wiring including a first capacitor wiring and a second capacitor wiring spaced apart from each other. The plurality of penetration structures includes a first penetration structure and a second penetration structure. The first penetration structure is electrically coupled with the first capacitor wiring and is electrically insulated from an insulated wiring portion. The insulated wiring portion is a second one of the first wiring portion and the second wiring portion. The second penetration structure is electrically coupled with the second capacitor wiring and is electrically insulated from the insulated wiring portion.

According to an aspect of the present disclosure, a capacitor structure may have a vertical capacitor that includes a plurality of penetration structures, and the capacitor structure may have a large capacitance in a relatively small area. The plurality of penetration structures may be electrically connected to at least one (e.g., a connection wiring portion) of first wiring portions or second wiring portions and may be electrically insulated from the other portion (e.g., an insulated wiring portion) of the at least one of the first wiring portions and the second wiring portions. Thus, the plurality of penetration structures and the insulated wiring portion may be freely disposed. Accordingly, properties of the capacitor structure and/or properties of the insulated wiring portion may be enhanced and thus performance of the semiconductor device may be enhanced, when compared to a related semiconductor device.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a plan view that schematically illustrates a semiconductor device, according to an embodiment;

FIG. 2 is a partial cross-sectional view that schematically illustrates the semiconductor device illustrated in FIG. 1, according to an embodiment;

FIG. 3 is an enlarged cross-sectional view that illustrates an example of a channel structure included in the semiconductor device illustrated in FIG. 2, according to an embodiment;

FIG. 4 is a partial plan view that illustrates a capacitor structure included in the semiconductor device illustrated in FIG. 1, according to an embodiment;

FIG. 5 is a partial cross-sectional view that illustrates the capacitor structure, a penetrating plug, and first and second wiring portions included in the semiconductor device illustrated in FIG. 1, according to an embodiment;

FIG. 6 is a partial cross-sectional view that illustrates a capacitor structure, a penetrating plug, and first and second wiring portions included in a semiconductor device, according to a modified embodiment;

FIG. 7 is a partial plan view that illustrates a capacitor structure included in a semiconductor device, according to an embodiment;

FIG. 8 is a partial cross-sectional view that illustrates a capacitor structure, a penetrating plug, and first and second wiring portions included in a semiconductor device, according to an embodiment;

FIG. 9 is a partial plan view that illustrates the capacitor structure illustrated in FIG. 8, according to an embodiment;

FIG. 10 is a partial plan view that illustrates a capacitor structure included in a semiconductor device, according to an embodiment;

FIG. 11 is a partial cross-sectional view that illustrates a capacitor structure, a penetrating plug, and first and second wiring portions included in a semiconductor device, according to a modified embodiment;

FIG. 12 schematically illustrates an electronic system that includes a semiconductor device, according to an embodiment;

FIG. 13 is a perspective view that schematically illustrates an electronic system including a semiconductor device, according to an embodiment; and

FIG. 14 is a cross-sectional view that schematically illustrates a semiconductor package, according to an embodiment.

### DETAILED DESCRIPTION

Embodiments of the present disclosure are described hereinafter with reference to the accompanying drawings for those skilled in the art to which the present disclosure pertains to practice the present disclosure. The present disclosure may be implemented in various different forms and is not limited to the embodiments provided herein.

A portion unrelated to the description may be omitted in order to clearly describe the present disclosure, and the same and/or similar components are denoted by the same reference numeral throughout the present disclosure.

A size and/or a thickness of a portion, a region, a member, a unit, a layer, a film, a substrate, or the like illustrated in the accompanying drawings may be arbitrarily illustrated for better understanding and convenience of explanation, and as such, the present disclosure is not limited to the illustrated size and/or thickness. In the drawings, thicknesses of portions, regions, members, units, layers, films, or the like may be enlarged or exaggerated for convenience of explanation and/or simple illustration.

It is to be understood that when a component such as a portion, a region, a member, a unit, a layer, a film, a substrate, or the like is referred to as being “on” another component, the component may be directly on another component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

As used herein, unless explicitly described to the contrary, the word “comprise”, “include”, or “contain”, and variations such as “comprises”, “comprising”, “includes”, “including”, “contains” or “containing” are to be understood to imply the inclusion of other components rather than exclusion of any other components.

As used herein, a phrase “on a plane”, “in a plane”, “on a plan view”, or “in a plan view” may indicate a case where a portion is viewed from above or a top portion, and a phrase “on a cross-section” or “in a cross-sectional view” may indicate when a cross-section taken along a vertical direction is viewed from a side.

It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “SiC”, “SiCN”, “Si₃N₄”, “SiO₂”, “SiOₓN_{y}”, “TaN”, “TiN”, “WN”, and the like may refer to a material made of elements included in each of the terms and is not a chemical formula representing a stoichiometric relationship.

Hereinafter, a semiconductor device according to various embodiments of the present disclosure are described with reference to the accompanying drawings.

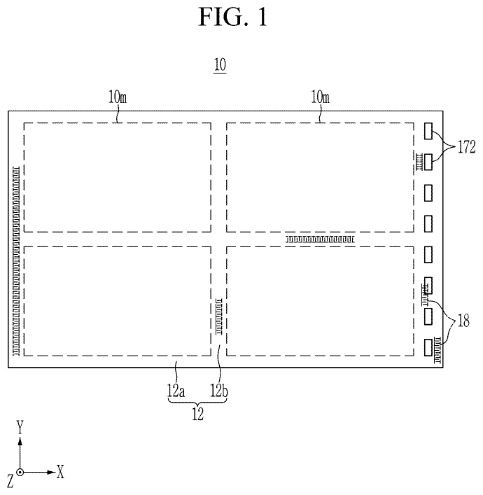

FIG. 1 is a plan view that schematically illustrates a semiconductor device 10, according to an embodiment.

Referring to FIG. 1, in an embodiment, a semiconductor device 10 may include a plurality of memory regions 10m that may be partitioned, separated, divided, and/or defined by an outer region 12.

The memory region 10m may be a unit region of the semiconductor device 10, and may be referred to as a MAT. In FIG. 1, it is illustrated as an example that the semiconductor device 10 may include a plurality of memory regions 10m that are adjacent to each other in a first direction (an X-axis direction), and may include a plurality of memory regions 10m that are adjacent to each other in a second direction (a Y-axis direction). However, the present disclosure is not limited thereto. A number, an arrangement, or the like of the plurality of memory regions 10m may be variously modified.

The outer region 12 may be disposed outside the plurality of memory regions 10m and may partition, separate, divide, and/or define the plurality of memory regions 10m. The outer region 12 may include at least one first outer region 12a and at least one second outer region 12b. The first outer region 12a may extend longitudinally in the first direction (the X-axis direction). The second outer region 12b may extend longitudinally in the second direction (the Y-axis direction). Thereby, a structure of the outer region 12 may be simplified. However, the present disclosure is not limited thereto. In some embodiments, the first and/or second outer region 12a and/or 12b may include a bent portion, a folded portion, a curved portion, a rounded portion, or the like according to an arrangement of the plurality of memory regions 10m.

In the outer region 12, an input/output pad 172 that is configured to be connected to an external circuit may be disposed. In FIG. 1, it is illustrated as an example that a plurality of input/output pads 172 are disposed to form a row in a portion adjacent to one edge of the semiconductor device 10. However, the present disclosure is not limited thereto, and various modifications are possible. The input/output pad 172 may be disposed to be adjacent to a plurality of edges of the semiconductor device 10, or may be disposed to form a plurality of rows.

In an embodiment, the semiconductor device 10 may include a capacitor structure 18. For example, the capacitor structure 18 may be used for a positive charge pump or a negative charge pump, may be used as an input/output capacitor configured to reduce noise, or may be used as a power capacitor. However, the present disclosure is not limited thereto, and the capacitor structure 18 may perform various functions.

In FIG. 1, it is illustrated as an example that the capacitor structure 18 is disposed in the outer region 12. However, the present disclosure is not limited thereto, and the capacitor structure 18 may be disposed in any of various positions. For example, in a plan view, the capacitor structure 18 may be disposed in a portion between the plurality of memory regions 10m, in a portion between the memory region 10m and the input/output pad 172, in a portion that overlaps the input/output pad 172, in a portion between the input/output pad 172 and an edge of the semiconductor device 10, and/or in a portion between the memory region 10m and the edge of the semiconductor device 10. However, the present disclosure is not limited thereto. Accordingly, a position, a shape, an arrangement, a number, or the like of the capacitor structure 18 may be variously modified. For example, the capacitor structure 18 may be disposed in a portion of the memory region 10m.

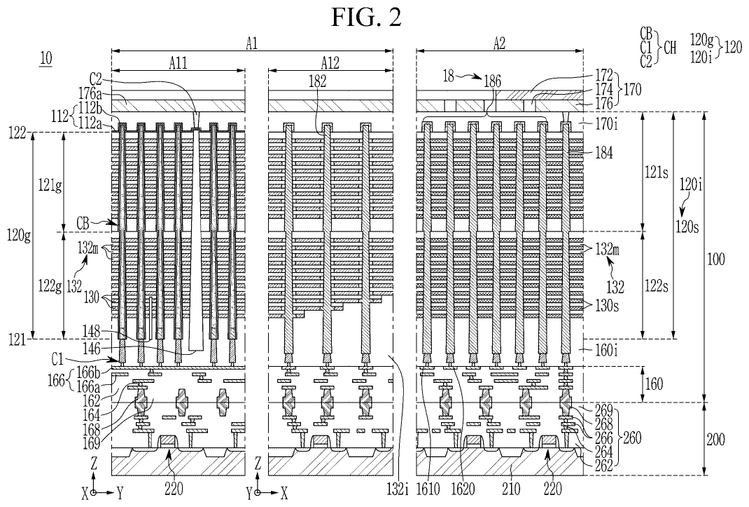

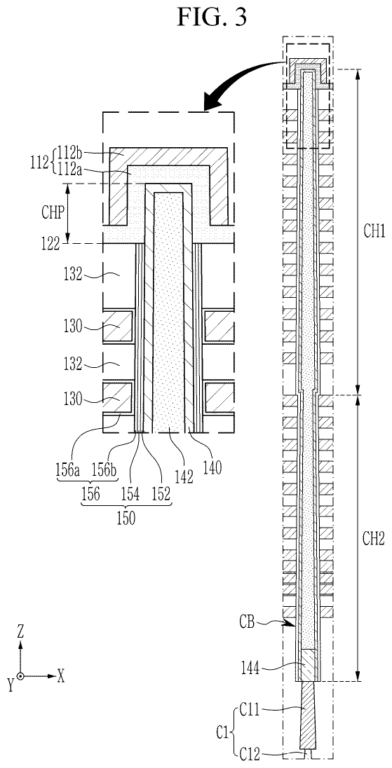

Referring to FIGS. 2 and 3, the semiconductor device 10, according to an embodiment, is further described.

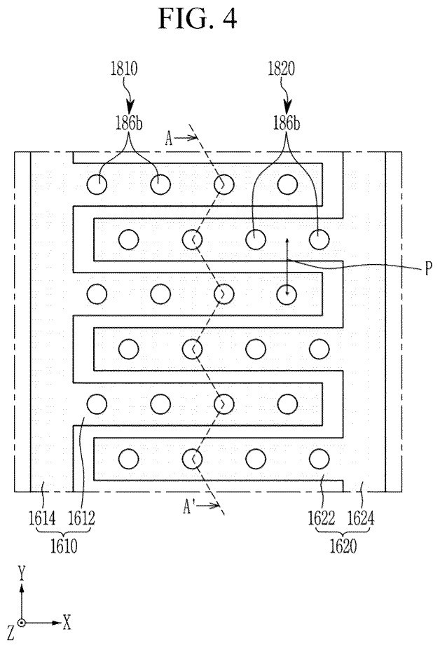

FIG. 2 is a partial cross-sectional view that schematically illustrates the semiconductor device 10 illustrated in FIG. 1. FIG. 3 is an enlarged cross-sectional view that illustrates an example of a channel structure CH included in the semiconductor device 10 illustrated in FIG. 2. For the sake of simplified description, in FIG. 2, a gate contact portion 182, a penetration structure 186 of a capacitor structure 18, and a penetrating plug 184 are illustrated together. However, positions of the gate contact portion 182, the penetration structure 186 of the capacitor structure 18, and the penetrating plug 184 may be variously modified. A cross-sectional view of the capacitor structure 18 taken along a line A-A′ in FIG. 4 is illustrated in FIG. 2.

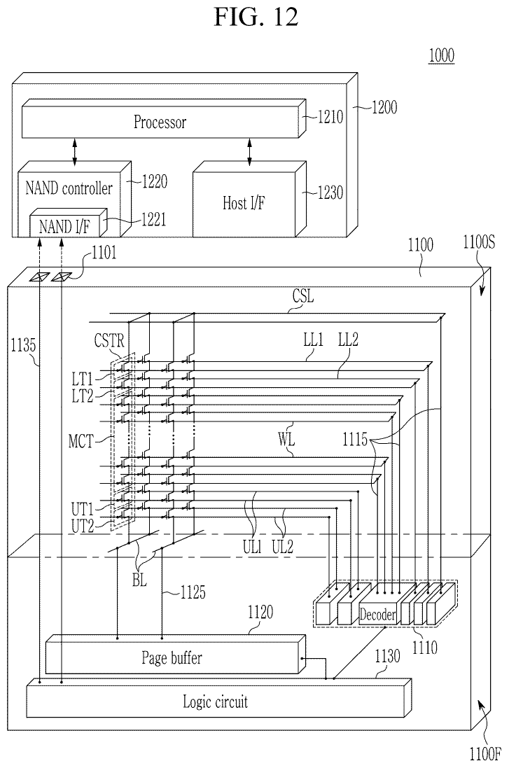

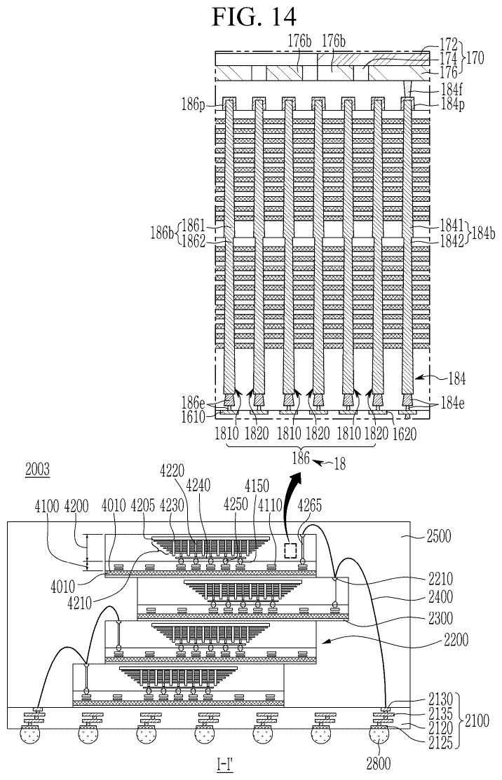

Referring to FIGS. 2 and 3, the semiconductor device 10, according to an embodiment, may include a cell region 100 that includes a memory cell structure and a circuit region 200 that includes a peripheral circuit structure configured to control an operation of the memory cell structure. For example, the circuit region 200 and the cell region 100 may correspond to a first structure 1100F and a second structure 1100S of a semiconductor device 1100 that is included in an electronic system 1000 illustrated in FIG. 12, respectively. For example, the circuit region 200 and the cell region 100 may be and/or may include portions that include a first structure 4100 and a second structure 4200 of a semiconductor chip 2200 illustrated in FIG. 14, respectively.

In an embodiment, the semiconductor device 10 may be and/or may include a bonding semiconductor device in which the cell region 100 and the circuit region 200 are bonded to each other. For example, the semiconductor device 10 may be and/or may include a bonding vertical NAND flash memory or a bonding vertical NAND (BV-NAND). The cell region 100 may be separately manufactured from the circuit region 200 and may be bonded to the circuit region 200 to form the semiconductor device 10. For example, the cell region 100 may be bonded to the circuit region 200 by a chip-to-chip (C2C) bonding process, a chip-to-wafer bonding process, and/or a wafer-to-wafer bonding process that may be referred to as a hybrid bonding process. By manufacturing the cell region 100 and the circuit region 200 using separate processes, it may be possible to prevent the circuit region 200 from being adversely affected when the cell region 100 is formed.

In an embodiment, the circuit region 200 may include a substrate 210, a circuit element 220, and a second wiring portion 260. In some embodiments, the circuit region 200 may further include an input/output pad other than the input/output pad 172 included in the cell region 100.

The substrate 210 may be and/or may include a semiconductor substrate that includes a semiconductor material. For example, the substrate 210 may be and/or may include a semiconductor substrate that includes or is formed of a semiconductor material or may be a semiconductor substrate in which a semiconductor layer is on a base substrate. For example, the substrate 210 may include single-crystalline or polycrystalline silicon, epitaxial silicon, germanium (Ge), silicon-germanium (Si-Ge), silicon on insulator (SOI), germanium on insulator (GOI), or the like.

The circuit element 220 on the substrate 210 may include any of various circuit elements and may constitute the peripheral circuit structure that controls an operation of the memory cell structure included in the cell region 100. For example, the circuit element 220 may constitute the peripheral circuit structure such as, but not limited to, a decoder circuit (e.g., a decoder circuit 1110 of FIG. 12), a page buffer (e.g., a page buffer 1120 of FIG. 12), a logic circuit (e.g., a logic circuit 1130 of FIG. 12), or the like.

The circuit element 220 may include a transistor, but the present disclosure is not limited thereto. For example, the circuit element 220 may include not only an active element such as the transistor or the like but may also include a passive element such as, but not limited to, a capacitor, a resistor, an inductor, or the like.

The circuit wiring portion 260 disposed on the substrate 210 may be electrically connected to the circuit element 220. For example, the circuit wiring portion 260 may include a plurality of wiring layers 266, a bonding structure 268, and a bonding insulation layer 269. The plurality of wiring layers 266 may be spaced apart from each other while interposing an insulation layer 262 therebetween and may be electrically connected by a contact via 264 to form a desired path. The bonding structure 268 may be electrically connected to the plurality of wiring layers 266 and may be disposed in a portion facing or being adjacent to the cell region 100. The bonding insulation layer 269 may be disposed at a periphery of the bonding structure 268 in the portion facing or being adjacent to the cell region 100.

The wiring layer 266 or the contact via 264 may include or be formed of any of various conductive materials, and the insulation layer 262 may include or be formed of any of various insulating materials. The bonding structure 268 and the bonding insulation layer 269 of the circuit region 200 are further described below.

In an embodiment, the cell region 100 may include a cell structure 120, a first wiring portion 160, a second wiring portion 170, a channel structure CH, and a capacitor structure 18. The first wiring portion 160 and the second wiring portion 170 may be disposed on a first surface 121 and a second surface 122 of the cell structure 120 that are opposite to each other. The cell region 100 may further include a gate contact portion 182, a first insulation portion 160i, a second insulation portion 170i, or the like. The first surface 121 of the cell structure 120 may refer to a surface that is on the same plane as an upper surface (e.g., a lower surface in FIG. 2) of a channel body portion CB (e.g., a channel pad 144), and the second surface 122 of the cell structure 120 may refer to a surface that is on the same plane as a lower surface (e.g., an upper surface in FIG. 2) of a lowest insulation layer (e.g., a highest insulation layer in FIG. 2) included in the cell structure 120.

The cell structure 120 may include a gate stacking structure 120g that is disposed in a first region A1 and an insulation structure 120i that is disposed in a second region A2. The first region A1 may be a region in which the gate stacking structure 120g is disposed. The second region A2 may be a region other than the first region A1 and may be a region in which the insulation structure 120i is disposed without the gate stacking structure 120g. The terms of the first region A1 and the second region A2 are used to distinguish them, however, the present disclosure is not limited to the terms of the first region A1 and the second region A2.

The first region A1 may correspond to at least a portion of the memory region 10m. The first region A1 may include a cell array region A11 and a connection region A12. The connection region A12 may be disposed at a periphery of the first region A1. In the cell array region A11, the gate stacking structure 120g and the channel structure CH may be included as a memory cell structure. In the connection region A12, a structure (e.g., the gate contact portion 182) that is configured to electrically connect a gate electrode 130 included in the gate stacking structure 120g to the circuit portion 200 may be disposed. The second region A2 may include the outer region 12, and may further include a portion of the memory region 10m.

In an embodiment, the gate stacking structure 120g may include a plurality of cell insulation layers 132 (e.g., a plurality of interlayer insulation layers 132m) and a plurality of gate electrodes 130 that are alternately stacked to each other. In the cell array region A11, the gate stacking structure 120g may be disposed between the first surface 121 and the second surface 122 of the cell structure 120. In the connection region A12, the gate stacking structure 120g and the cell insulation layer 132 (e.g., an upper insulation layer 132i) that may cover the gate stacking structure 120g may be disposed between the first surface 121 and the second surface 122 of the cell structure 120.

The insulation structure 120i may be disposed to correspond to the gate stacking structure 120g in a thickness direction of the semiconductor device 10 (a Z-axis direction). For example, a first surface (a lower surface in FIG. 2) of the insulation structure 120i in the second region A2 may include a portion that is disposed on the same plane as a first surface (e.g., a lower surface in FIG. 2) of the gate stacking structure 120g in the cell array region A11. The first surface (e.g., the lower surface in FIG. 2) of the insulation structure 120i may be adjacent to the circuit region 200 and the first surface (e.g., the lower surface in FIG. 2) of the gate stacking structure 120g may be adjacent to the circuit region 200. For example, a second surface (e.g., an upper surface in FIG. 2) of the insulation structure 120i in the second region A2 may include a portion that is disposed on the same plane as a second surface (e.g., an upper surface in FIG. 2) of the gate stacking structure 120g in the cell array region A11. The second surface (e.g., the upper surface in FIG. 2) of the insulation structure 120i may be opposite to the circuit region 200 and the second surface (e.g., the upper surface in FIG. 2) of the gate stacking structure 120g may be opposite to the circuit region 200. That is, in the first surface 121 of the cell structure 120, the first surface of the gate stacking structure 120g and the first surface of the insulation structure 120i may be disposed on the same plane, and, in the second surface 122 of the cell structure 120, the second surface of the gate stacking structure 120g and the second surface of the insulation structure 120i may be disposed on the same plane.

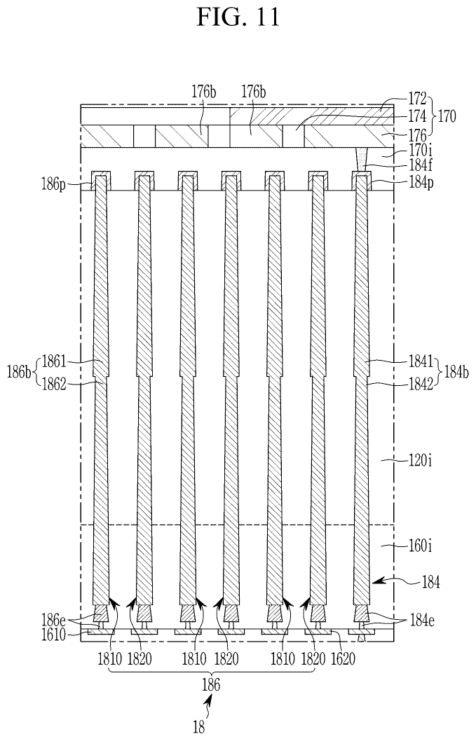

In an embodiment, the insulation structure 120i may include a sacrificial stacking structure 120s. The sacrificial stacking structure 120s may include the plurality of cell insulation layers 132 (e.g., the plurality of interlayer insulation layers 132m) and a plurality of sacrificial insulation layers 130s that are alternately stacked to each other. The plurality of interlayer insulation layers 132m of the gate stacking structure 120g and the plurality of interlayer insulation layers 132m of the sacrificial stacking structure 120s may be formed by the same process. For example, the sacrificial stacking structure 120s may be formed by alternately stacking the plurality of interlayer insulation layers 132m and the plurality of sacrificial insulation layers 130s in the first region A1 and the second region A2, and then, the plurality of sacrificial insulation layers 130s in the first region A1 may be replaced with the plurality of gate electrodes 130, respectively. Accordingly, the gate stacking structure 120g may be disposed in the first region A1, and the sacrificial stacking structure 120s may be remained in the second region A2. Thereby, a process of removing a portion of the sacrificial stacking structure 120s in the second region A2 may be omitted and thus there may be no need to consider a margin due to a process error or the like. Accordingly, the semiconductor device 10 may be formed by a relatively simple process and an area of the semiconductor device 10 may be reduced, when compared to a related semiconductor device. Other embodiments are further described with reference to FIG. 11.

The gate electrode 130 may include or be formed of any of various conductive materials. For example, the gate electrode 130 may include or be formed of a metal material (e.g., tungsten (W), copper (Cu), aluminum (Al), or the like), polycrystalline silicon, metal nitride (e.g., titanium nitride (TiN), tantalum nitride (TaN), tungsten nitride (WN), or the like), or a combination thereof. The cell insulation layer 132 may include or be formed of any of various insulating materials. For example, the cell insulation layer 132 (e.g., the interlayer insulation layer 132m or the upper insulation layer 132i) may include or be formed of silicon oxide (SiO₂), silicon nitride (Si₃N₄), silicon oxynitride (SiOₓN_{y}), a low dielectric constant material that has a lower dielectric constant than silicon oxide (SiO₂), or a combination thereof.

The sacrificial insulation layer 130s may include or be formed of a material that is different from a material of the cell insulation layer 132 (e.g., the interlayer insulation layer 132m). For example, the sacrificial insulation layer 130s may include or be formed of silicon (Si), silicon oxide (SiO₂), silicon carbide (SiC), silicon nitride (Si₃N₄), or the like that is different from a material of the cell insulation layer 132 (e.g., the interlayer insulation layer 132m).

In an embodiment, the gate stacking structure 120g may include a plurality of gate stacking portions (e.g., a first gate stacking portion 121g and a second gate stacking portion 122g) that are sequentially stacked in the thickness direction of the semiconductor device 10 (the Z-axis direction). Thereby, a number of stacked gate electrodes 130 may be increased and thus a number of memory cells may be increased with a stable structure. The insulation structure 120i or the sacrificial stacking structure 120s may include a plurality of insulation stacking portions (e.g., a first insulation stacking portion 121s and a second insulation stacking portion 122s) that are sequentially stacked in the thickness direction of the semiconductor device 10. The plurality of insulation stacking portions 121s and 122s may correspond to the plurality of gate stacking portions 121g and 122g, respectively.

Each first or second gate stacking portion 121g or 122g may be a region that is regarded as one unit region in a manufacturing process. For example, each first or second gate stacking portion 121g or 122g or each first or second insulation stacking portion 121s or 122s may be one unit region in a manufacturing process of penetration regions for the channel body portion CB, the gate contact portion 182, the penetrating plug 184, the penetration structure 186, or the like. That is, the first insulation stacking portion 121s may be formed and then a portion (e.g., a first penetration portion) of the penetration region that passes through or penetrates the first insulation stacking portion 121s may be formed. The second insulation stacking portion 122s may be formed and then a portion (e.g., a second penetration portion) of the penetration region that passes through or penetrates the second insulation stacking portion 122s may be formed. Thereby, one penetration region that includes the first penetration portion and the second penetration portion may be formed. Accordingly, at a boundary of the first and second gate stacking portions 121g and 122g or a boundary of the first and second insulation stacking portions 121s and 122s, the channel body portion CB, the gate contact portion 182, the penetrating plug 184, the penetration structure 186, or the like may have a bent portion. However, the present disclosure is not limited thereto.

In FIG. 2, it is illustrated as an example that the gate stacking structure 120g includes first and second gate stacking structures 121g and 122g and the insulation structure 120i includes first and second insulation stacking structures 121s and 122s. However, the present disclosure is not limited thereto. The gate stacking structure 120g may include one (1) gate stacking portion or three (3) or more gate stacking portions, and/or the insulation structure 120i may include one insulation stacking portion or three (3) or more insulation stacking portions that correspond to the three (3) or more gate stacking portions, respectively.

In an embodiment, the channel structure CH that passes through or penetrates the gate stacking structure 120g may be disposed in the cell array region A11 of the first region A1, and the plurality of gate contact portions 182 that are connected to the plurality of gate electrodes 130 included in the gate stacking structure 120g may be disposed in the connection region A12 of the first region A1. In the second region A2, the plurality of penetration structures 186 and the penetrating plug 184 may be disposed. The plurality of penetration structures 186 may pass through or penetrate at least a portion of the insulation structure 120i and may be included in the capacitor structure 18. The penetrating plug 184 may pass through or penetrate the insulation structure 120i. The channel structure CH, the gate contact portion 182, the plurality of penetration structures 186 that are included in the capacitor structure 18, and the penetrating plug 184 are further described after describing the first insulation portion 160i, the second insulation portion 170i, the first wiring portion 160, and the second wiring portion 170.

In the first region A1, the gate stacking structure 120g may be divided and/or partitioned into a plurality of portions in a plan view by a separation structure 146 in a plan view. The separation structure 146 may pass through the gate stacking structure 120g. An upper separation region 148 may be disposed at an upper portion (a lower portion in FIG. 2) of the gate stacking structure 120g. In a plan view, the separation structure 146 and/or the upper separation region 148 may extend in the first direction (the X-axis direction). A plurality of separation structures 146 and/or a plurality of upper separation regions 148 may be spaced apart from each other at predetermined intervals in the second direction (the Y-axis direction) that crosses (e.g., is perpendicular to) the first direction.

In a plan view, the plurality of gate stacking structures 120g may each extend in the first direction (the X-axis direction) and be spaced apart from each other at a predetermined interval in the second direction (the X-axis direction) that crosses the first direction by the separation structure 146. The gate stacking structure 120g divided by the separation structure 146 may constitute one memory cell block. However, the present disclosure is not limited thereto, and a range of the memory cell block is not limited thereto.

For example, the separation structure 146 may extend from the first surface of the gate stacking structure 120g and the second surface of the gate stacking structure 120g to pass through or penetrate the gate stacking structure 120g, and the upper separation region 148 may separate one or a part of the plurality of gate electrodes 130 at a side of the first surface of the gate stacking structure 120g. The upper separation region 148 may be disposed between the separation structures 146. For example, an extension direction of the separation structure 146 or the upper separation region 148 may be the thickness direction of the semiconductor device 10 and may be the Z-axis direction.

For example, in a cross-sectional view, the separation structure 146 may have an inclined side surface such that a width of the separation structure 146 gradually decreases toward the second wiring portion 170 due to a high aspect ratio. However, the present disclosure is not limited thereto. In some embodiments, a side surface of the separation structure 146 may have a vertical surface that may be parallel to the thickness direction of the semiconductor device 10 or may be perpendicular to the semiconductor device 10. In some embodiments, the separation structure 146 may have a bent portion at the boundary of the first and second gate stacking portions 121g and 122g.

The separation structure 146 and/or the upper separation region 148 may include or be formed of any of various insulating materials. For example, the separation structure 146 or the upper separation region 148 may include or be formed of an insulating material such as, but not limited to, silicon oxide (SiO₂), silicon nitride (Si₃N₄), or silicon oxynitride (SiOₓN_{y}). However, the present disclosure is not limited thereto, and a structure, a shape, a material, or the like of the separation structure 146 or the upper separation region 148 may be variously modified.

The first wiring portion 160 may be disposed on the first surface 121 of the cell structure 120 while interposing the first insulation portion 160i, and the second wiring portion 170 may be disposed on the second surface 122 of the cell structure 120 while interposing the second insulation portion 170i. That is, the first insulation portion 160i may be disposed on the first surface 121 of the cell structure 120 (e.g., at a lower portion of the cell structure 120 in FIG. 2), and the first wiring portion 160 may be disposed on the first insulation portion 160i (e.g., at a lower portion of the first insulation portion 160i in FIG. 2). The second insulation portion 170i may be disposed on the second surface 122 of the cell structure 120 (e.g., at an upper portion of the cell structure 120 in FIG. 2), and the second wiring portion 170 may be disposed on the second insulation portion 170i (e.g., at an upper portion of the second insulation portion 170i). The terms of first and second are used to distinguish them. However, the present disclosure is not limited to the terms of first and second.

The first insulation portion 160i that is disposed between the cell structure 120 and the first wiring portion 160 may include or be formed of any of various insulating materials. For example, the first insulation portion 160i may include or be formed of silicon oxide (SiO₂), silicon nitride (Si₃N₄), silicon oxynitride (SiOₓN_{y}), or combination thereof, but the present disclosure is not limited thereto. The first insulation portion 160i may include a single layer or a plurality of layers.

The first wiring portion 160 may electrically connect the gate electrode 130, the channel structure CH, and the second wiring portion 170 to the circuit region 200. The first wiring portion 160 may transfer a signal and/or a voltage from the circuit region 200 to the first surface 121 of the cell structure 120, and/or transfer a signal or a voltage from the cell region 100 to the circuit region 200.

For example, the first wiring portion 160 may include a plurality of first wiring layers 166, a bonding structure 168, and a bonding insulation layer 169. The plurality of first wiring layers 166 may be spaced apart from each other while interposing a first insulation layer 162 therebetween and may be electrically connected by a first contact via 164 to form a desired path. The bonding structure 168 may be electrically connected to the plurality of first wiring layers 166 and may be disposed in a portion facing or being adjacent to the circuit region 200. The bonding insulation layer 169 may be disposed at a periphery of the bonding structure 168 in the portion facing or being adjacent to the circuit region 200.

The first wiring layer 166 may include a bit line 166b, a connection wiring 166a, or the like. The bit line 166b may extend in the second direction (the Y-axis direction) that is transverse to or crosses the first direction (the X-axis direction) in which the gate electrode 130 extends. The bit line 166b may be electrically connected to the channel structure CH (e.g., the channel pad 144). The connection wiring 166a may be connected to the bit line 166b, the gate contact portion 182, the penetrating plug 184, or the like.

In an embodiment, the first wiring layer 166 may include a capacitor wiring that includes a first capacitor wiring 1610 and a second capacitor wiring 1620. These elements are further described below.

The first wiring layer 166 or the first contact via 164 may include or be formed of any of various conductive materials, and the first insulation layer 162 may include or be formed of any of various insulating materials. The bonding structure 168 and the bonding insulation layer 169 of the cell region 100 are further described below.

The second insulation portion 170i that is disposed between the cell structure 120 and the second wiring portion 170 may include or be formed of any of various insulating materials. For example, the second insulation portion 170i may include or be formed of silicon oxide (SiO₂), silicon nitride (Si₃N₄), silicon oxynitride (SiOₓN_{y}), or combination thereof, but the present disclosure is not limited thereto. The second insulation portion 170i may include a single layer or a plurality of layers.

The second wiring portion 170 may transfer a voltage and/or a signal that may be applied through the input/output pad 172 to the cell region 100 or the circuit region 200, and/or transfer a voltage and/or a signal from the circuit region 200 to the second surface 122 of the cell structure 120. For example, a voltage that is generated from the circuit region 200 may be transferred to a horizontal conductive portion 112 that acts as a common source line through a source wiring layer 176a.

For example, the second wiring portion 170 may include a second wiring layer 176 and the input/output pad 172. The second wiring layer 176 may include the source wiring layer 176a that is disposed on the second insulation portion 170i. The input/output pad 172 may be connected to the second wiring layer 176. The second wiring portion 170 may further include a second insulation layer 174 that is disposed at a periphery of the second wiring layer 176 or the input/output pad 172. In FIG. 2, it is illustrated as an example that the source wiring layer 176a or the second wiring layer 176 includes or is formed of a single layer, but the present disclosure is not limited thereto.

The source wiring layer 176a may be electrically connected to a second channel connecting portion C2 that passes through or penetrates the second insulation portion 170i. For example, the source wiring layer 176a may be electrically connected to the horizontal conductive portion 112 that is electrically connected to the channel body portion CB through the second channel connecting portion C2. The source wiring layer 176a may include or be formed of a conductive material. For example, the source wiring layer 176a may include or be formed of a metal material such as tungsten (W), copper (Cu), aluminum (Al), or the like. The source wiring layer 176a may have any of various shapes that provide an electrical connection passage, but the present disclosure is not limited thereto.

In an embodiment, in the first region A1 (e.g., the cell array region A11 of the first region A1), the channel structure CH may pass through or penetrate the gate stacking structure 120g and may be electrically connected to the first wiring portion 160 and the second wiring portion 170.

For example, the channel structure CH may include a channel body portion CB, a first channel connecting portion C1, and a second channel connecting portion C2. The channel body portion CB may extend in an extension direction and pass through or penetrate the gate stacking structure 120g. The first channel connecting portion C1 may pass through or penetrate the first insulation portion 160i and electrically connect the channel body portion CB and the first wiring portion 160. The second channel connecting portion C2 may pass through or penetrate the second insulation portion 170i and may electrically connect the channel body portion CB and the second wiring portion 170. The horizontal conductive portion 112 may be disposed between the channel body portion CB and the second channel connecting portion C2. An extension direction of the channel structure CH may be the thickness direction of the semiconductor device 10 or the direction that is perpendicular to the semiconductor device 10, and may be the Z-axis direction.

The channel body portion CB of the channel structure CH may include a channel layer 140, and a gate dielectric layer 150 on the channel layer 140 between the gate electrode 130 and the channel layer 140. The gate dielectric layer 150 between the gate electrode 130 and the channel layer 140 may include a tunneling layer 152, a charge storage layer 154, and a blocking layer 156 sequentially on the channel layer 140.

The channel body portion CB may further include a core insulation layer 142 at an inside of the channel layer 140. In some embodiments, the core insulation layer 142 may be omitted. The channel body portion CB of the channel structure CH may further include the channel pad 144 on the channel layer 140 and/or the gate dielectric layer 150. The channel pad 144 may cover an upper surface (e.g., a lower surface in FIG. 2 or FIG. 3) of the core insulation layer 142 and may be electrically connected to the channel layer 140.

The channel layer 140 may include or be formed of a semiconductor material (e.g., polycrystalline silicon). The core insulation layer 142 may include or be formed of any of various insulating materials. For example, the core insulation layer 142 may include or be formed of silicon oxide (SiO₂), silicon nitride (Si₃N₄), silicon oxynitride (SiOₓN_{y}), or a combination thereof. The channel pad 144 may include or be formed of a conductive material (e.g., polycrystalline or single-crystalline silicon doped with a dopant).

The tunneling layer 152 may include or be formed of an insulating material (e.g., silicon oxide (SiO₂), silicon oxynitride (SiOₓN_{y}), or the like) that may be capable of tunneling a charge. The charge storage layer 154 may be used as a data storage region. The charge storage layer 154 may include or be formed of polycrystalline silicon, silicon nitride (Si₃N₄), or the like. The blocking layer 156 may include or be formed of an insulating material that may be capable of preventing an undesirable flow of charge into the gate electrode 130. For example, the blocking layer 156 may include or be formed of silicon oxide (SiO₂), silicon nitride (Si₃N₄), silicon oxynitride (SiOₓN_{y}), a high dielectric constant material that has a higher dielectric constant than silicon oxide (SiO₂), or a combination thereof. In an embodiment, the blocking layer 156 may include a first blocking layer 156a that includes a portion horizontally extending on the gate electrode 130, and a second blocking layer 156b that vertically extends between the first blocking layer 156a and the charge storage layer 154.

However, the present disclosure is not limited to a material, a structure, or the like of the channel layer 140, the core insulation layer 142, and the gate dielectric layer 150.

Each channel body portion CB may form one memory cell string, and a plurality of channel structures CH may be spaced apart from each other to form rows and columns in a plan view. For example, in a plan view, the plurality of channel boding portions CB may be disposed to have any of various shapes, such as, a lattice shape, a zigzag shape, or the like. The channel body portion CB may have a pillar shape. For example, in a cross-sectional view, the channel body portion CB may have an inclined side surface so that a width of the channel body portion CB decreases as the channel body portion CB goes to the second wiring portion 170 due to a high aspect ratio. However, the present disclosure is not limited thereto, and an arrangement, a structure, a shape, or the like of the channel structure CH or the channel body portion CB may be variously modified.

When the plurality of gate stacking portions 121g and 122g are provided as in the above, the channel body portion CB may include a plurality of channel portions CH1 and CH2 that may respectively pass through the plurality of gate stacking portions 121g and 122g. The plurality of channel portions CH1 and CH2 may be connected to each other. In a cross-sectional view, each of the plurality of channel portions CH1 and CH2 may have an inclined side surface such that a width of each of the plurality of channel portions CH1 and CH2 decreases toward the second wiring portion 170 due to a high aspect ratio. A bent portion due to a difference in widths of the plurality of channel portions CH1 and CH2 may be provided at a boundary of the plurality of channel portions CH1 and CH2. In some embodiments, the channel body portion CB may have an inclined side surface that may continuously extend without the bent portion. In FIG. 3, it is illustrated as an example that each of the gate dielectric layer 150, the channel layer 140, and the core insulation layer 142 of the plurality of channel portions CH1 and CH2 continuously extends to have an integral structure. In some embodiments, gate dielectric layers 150, channel layers 140, and core insulation layers 142 of the plurality of channel portions CH1 and CH2 may be separately formed and be electrically connected to each other. In some embodiments, a separate channel pad may be additionally at the boundary of the plurality of channel portions CH1 and CH2. As such, the present disclosure is not limited to the shape of the plurality of channel portions CH1 and CH2.

The channel body portion CB may include a protrusion portion CHP that protrude than the second surface 122 of the cell structure 120. The gate dielectric layer 150 may not be disposed in the protrusion portion CHP and the channel layer 140 disposed in the protrusion portion CHP may be exposed to an outside of the cell structure 120.

In the first region A1, the horizontal conductive portion 112 may be disposed on the second surface 122 of the gate stacking structure 120g and the plurality of protrusion portions CHP that are included in the plurality of channel body portions CB. The horizontal conductive portion 112 may be connected to the plurality of channel body portions CB and thus act as a common source line. For example, the horizontal conductive portion 112 may be connected (e.g., directly connected) to the channel layer 140 in the protrusion portion CHP of the channel body portion CB. However, the present disclosure is not limited thereto. The common source line that is connected to the channel body portion CB may have any of various structure. By the horizontal conductive portion 112, a connection structure between the second channel connecting portion C2 (e.g., a contact via included in the second channel connecting portion C2) and the plurality of channel body portions CB may be simplified.

The horizontal conductive portion 112 may include a horizontal conductive layer 112a and a metal layer 112b. The horizontal conductive layer 112a may be connected (e.g., directly connected) to the plurality of channel body portions CB. The metal layer 112b may be disposed on the horizontal conductive layer 112a.

The horizontal conductive layer 112a may include a semiconductor layer that includes an n-type dopant or a p-type dopant. The n-type dopant may include any of group V elements, and p-type dopant may include any of group III elements. For example, the n-type dopant may include or be formed of phosphorous (P), arsenic (As), antimony (Sb), or the like, and the p-type dopant may include or be formed of boron (B), aluminum (Al), indium (In), gallium (Ga), or the like. However, the present disclosure is not limited thereto. For example, any of various materials or elements other than the above material or the group III or V elements may be used as a p-type or an n-type dopant. The metal layer 112b may include or be formed of a metal and thus may reduce electrical resistance between the horizontal conductive layer 112a and the second channel connecting portion C2.

In the above description, it is described as an example that the horizontal conductive layer 112a includes a single layer and the metal layer 112b includes a single layer, but the present disclosure is not limited thereto. In some embodiments, the horizontal conductive layer 112a may include a first horizontal conductive layer and a second horizontal conductive layer that have different conductive types from each other, and the metal layer 112b may include a first metal layer and a second metal layer that are electrically connected to the first horizontal conductive layer and the second horizontal conductive layer, respectively. In some embodiments, the horizontal conductive layer 112a and/or the metal layer 112b may include a plurality of layers, or the metal layer 112b may be omitted.

The first channel connecting portion C1 of the channel structure CH may include a member, a portion, a layer, a via, or the like that passes through or penetrates the first insulation portion 160i to electrically connect the channel body portion CB and the first wiring portion 160. For example, the first channel connecting portion C1 may include a channel stud C11 and a channel contact via C12. The channel stud C11 may be electrically connected (e.g., directly connected) to the channel pad 144, and the channel contact via C12 may electrically connect (e.g., directly connect) the channel stud C11 and the first wiring portion 160.

The second channel connecting portion C1 of the channel structure CH may include a member, a portion, a layer, a via, or the like that passes through or penetrates the second insulation portion 170i to electrically connect the channel body portion CB and the second wiring portion 170. For example, the second channel connecting portion C2 of the channel structure CH may include a contact via that passes through or penetrates the second insulation portion 170i to electrically connect the channel body portion CB and the second wiring portion 170. That is, the contact via of the second channel connecting portion C2 may electrically connect (e.g., directly connect) the horizontal conductive portion 112 that is connected to the protrusion portion CHP of the channel body portion CB and the second wiring portion 170.

In an embodiment, in the first region A1 (e.g., the connection region A12 of the first region A1), the gate contact portion 182 may pass through or penetrate the gate stacking structure 120g. In the connection region A12, the plurality of gate electrodes 130 may extend in the first direction (the X-axis direction). Extension lengths of the plurality of gate electrodes 130 may sequentially decrease in a direction away from the second wiring portion 170. For example, the plurality of gate electrodes 130 may have a stair shape in one direction or a plurality of directions in the connection region A12. In the connection region A12, a plurality of gate contact portions 182 may pass through the cell insulation layer 132 (e.g., the upper insulation layer 132i) to be electrically connected to the plurality of gate electrodes 130, respectively, that extend to the connection region A12.

In FIG. 2, it is illustrated as an example that the gate contact portion 182 may entirely pass through or penetrate the gate stacking structure 120g. For example, the gate contact portion 182 may be electrically connected to a connection gate electrode among the plurality of gate electrodes 130 that are included in the gate stacking structure 120g, and may be insulated from remain gate electrodes among the plurality of gate electrodes 130 while interposing an insulation pattern. Thereby, the gate contact portion 182 may be connected to the circuit region 200 through the first wiring portion 160, and thus, the first wiring portion 160 and/or the second wiring portion 170 may be freely disposed. However, a connection structure of the gate contact portion 182 and the circuit region 200 may be variously modified. In some embodiments, the gate contact portion 182 may be electrically connected to the gate electrode 130 by passing through or penetrating the cell insulation layer 132 (e.g., the upper insulation layer 132i) that is disposed on the gate stacking structure 120g without passing through or penetrating the gate stacking structure 120g.

The gate contact portion 182 may include or be formed of any of various conductive materials. For example, the gate contact portion 182 may include or be formed of a metal material (e.g., tungsten (W), copper (Cu), aluminum (Al), or the like), polycrystalline silicon, metal nitride (e.g., titanium nitride (TiN), tantalum nitride (TaN), tungsten nitride (WN), or the like), or a combination thereof. The gate contact portion 182 may further include a diffusion barrier layer. However, the present disclosure is not limited to a material of the gate contact portion 182.

In FIG. 2, it is illustrated as an example that, in a cross-sectional view, the gate contact portion 182 has an inclined side surface such that a width of the gate contact portion 182 decreases toward the second wiring portion 170 due to a high aspect ratio, and has a bent portion at a boundary of the plurality of gate stacking portions 121g and 122g. However, the present disclosure is not limited thereto. In some embodiments, the gate contact portion 182 may not have the bent portion at the boundary of the plurality of gate stacking portions 121g and 122g.

In an embodiment, in the second region A2, the penetrating plug 184 may pass through or penetrate the insulation structure 120i. The penetrating plug 184 may pass through or penetrate the insulation structure 120i and be electrically connected to the first wiring portion 160 and the second wiring portion 170. In an embodiment, in the second region A2, the capacitor structure 18 may be disposed. The capacitor structure 18 may include the plurality of penetration structures 186, and each of the plurality of penetration structures 186 may pass through or penetrate a portion of the insulation structure 120i. The penetrating plug 184, and the plurality of penetration structures 186 that are included in the capacitor structure 18 are further described below.

In an embodiment, the cell region 100 and the circuit region 200 may be bonded by hybrid bonding. That is, the cell region 100 and the circuit region 200 may be bonded by hybrid bonding that includes metal bonding between the bonding structures 168 and 268 and insulation-layer bonding between the bonding insulation layers 169 and 269.

For example, the bonding structure 168 of the cell region 100 and/or the bonding structure 268 of the circuit region 200 may include or be formed of metal, for example, at least one of copper (Cu), aluminum (Al), tungsten (W), nickel (Ni), gold (Au), tin (Sn), manganese (Mn), cobalt (Co), titanium (Ti), tantalum (Ta), ruthenium (Ru), beryllium (Be), or an alloy including the same. For example, the bonding structure 168 of the cell region 100 and the bonding structure 268 of the circuit region 200 may include or be formed of copper (Cu) so that the cell region 100 and the circuit region 200 may be bonded (e.g., directly bonded) to each other by copper-to-copper (Cu—Cu) bonding.

For example, in a bonding surface of the insulation-layer bonding, the bonding insulation layer 169 of the cell region 100 and the bonding insulation layer 269 of the circuit region 200 may include or be formed of the same insulating material. For example, the bonding insulation layer 169 of the cell region 100 and/or the bonding insulation layer 269 of the circuit region 200 may include or be formed of silicon carbonitride (SiCN) at least in the boding surface. However, the present disclosure is not limited thereto. The bonding insulation layer 169 of the cell region 100 and/or the bonding insulation layer 269 of the circuit region 200 may include a material that is the same as or different from a material of the cell insulation layer 132 of the cell region 100 or the insulation layer 262 of the circuit region 200.

In an embodiment, the cell region 100, the circuit region 200, and the input/output pad 172 may be electrically connected to each other by the first wiring portion 160 and the second wiring portion 170 of the cell region 100, and the circuit wiring portion 260 of the circuit region 200. Thereby, a voltage and/or a signal that is applied through the input/output pad 172 may be applied to the cell region 100 and/or the circuit region 200, a voltage and/or a signal of the cell region 100 may be transferred to the circuit region 200, and a voltage and/or a signal of the circuit region 200 may be transferred to the cell region 100.

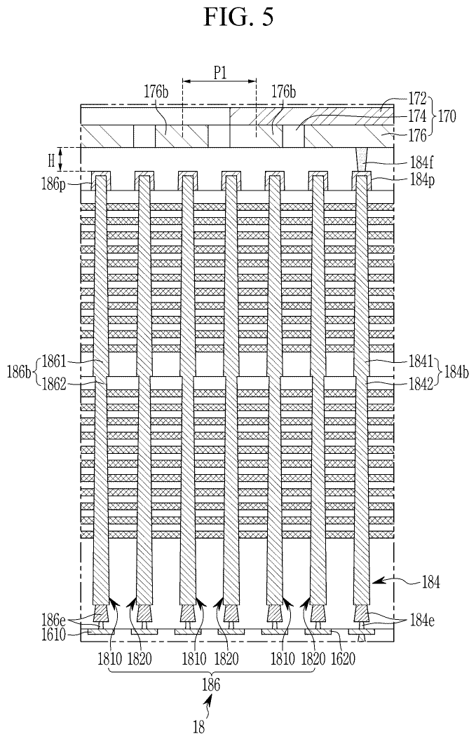

Referring to FIGS. 4 and 5 together with FIGS. 2 and 3, the penetrating plug 184, and the plurality of penetration structures 186 that are included in the capacitor structure 18 are further described below.

FIG. 4 is a partial plan view that illustrates the capacitor structure 18 included in the semiconductor device 10 illustrated in FIG. 1, according to an embodiment. FIG. 5 is a partial cross-sectional view that illustrates the capacitor structure 18, the penetrating plug 184, and the first and second wiring portions 160 and 170 included in the semiconductor device illustrated in FIG. 1, according to an embodiment. In FIG. 4, a penetration body portion 186b of the penetration structure 186 is mainly illustrated and a first capacitor connecting portion 186e may be omitted. A cross-sectional view of the capacitor structure 18 taken along the line A-A′ in FIG. 4 is illustrated in FIG. 5.

Referring to FIGS. 2 to 5, in an embodiment, the penetrating plug 184 may pass through or penetrate the insulation structure 120i and be electrically connect to the first wiring portion 160 and the second wiring portion 170. For example, the penetrating plug 184 may include a plug body portion 184b, a first plug connecting portion 184c, and a second plug connecting portion 184f. The plug body portion 184b may pass through or penetrate the insulation structure 120i. The first plug connecting portion 184e may pass through or penetrate the first insulation portion 160i and connect the plug body portion 184b and the first wiring portion 160. The second plug connecting portion 184f may pass through or penetrate the second insulation portion 170i and connect the plug body portion 184b and the second wiring portion 170.

The plug body portion 184b may have a pillar shape. When the plurality of gate stacking portions 121g and 122g are included, the plug body portion 184b may include a plurality of plug penetration portions 1841 and 1842 that are disposed to correspond to the plurality of gate stacking portions 121g and 122g, respectively. For example, when the insulation structure 120i may include or be formed of the sacrificial stacking structure 120s that includes the plurality of insulation stacking portions 121s and 122s, the plug body portion 184b may include the plurality of plug penetration portions 1841 and 1842 that pass through or penetrate the plurality of insulation stacking portions 121s and 122s, respectively.

In a cross-sectional view, each of the plurality of plug penetration portions 1841 and 1842 may have an inclined side surface such that a width of each of the plug penetration portions 1841 and 1842 gradually decreases toward the second wiring portion 170. A bent portion due to a difference in widths of the plurality of plug penetration portions 1841 and 1842 may be provided at a boundary of the plurality of plug penetration portions 1841 and 1842. In some embodiments, each of the plurality of plug penetration portions 1841 and 1842 may have an inclined side surface that continuously extends without the bent portion, or may have a side surface that extends in the vertical direction. The present disclosure is not limited to a shape of the plurality of plug penetration portions 1841 and 1842.

In FIGS. 2 and 5, it is illustrated as an example that the gate stacking structure 120g includes the first and second gate stacking structures 121g and 122g, the insulation structure 120i includes the first and second insulation stacking structures 121s and 122s, and the plug body portion 184b include first and second plug penetration portions 1841 and 1842. However, the present disclosure is not limited thereto. The plug body portion 184b may include a single plug penetration portion or three or more plug penetration portions.

The plug body portion 184b may include a protrusion portion that protrudes than the second surface 122 of the cell structure 120, and a landing pad 184p may be disposed on the protrusion portion of the plug body portion 184b. The landing pad 184p may be configured to prevent a damage of a preliminary substrate in a process of forming a penetration region for the plug body portion 184b and stably form the plug body portion 184b. However, the present disclosure is not limited thereto. In some embodiments, the landing pad 184p may be omitted.

The first plug connecting portion 184e may include a member, a portion, a layer, a via, or the like that passes through or penetrates the first insulation portion 160i to electrically connect the plug body portion 184b and the first wiring portion 160. For example, the first plug connecting portion 184e may include a stud and a contact via. The stud may be electrically connected (e.g., directly connected) to the plug body portion 184b, and the contact via may be electrically connect (e.g., directly connect) the stud and the first wiring portion 160.

The second plug connecting portion 184f may include a member, a portion, a layer, a via, or the like that passes through or penetrates the second insulation portion 170i to electrically connect the plug body portion 184b and the second wiring portion 170. For example, the second plug connecting portion 184f may include a contact via that passes through or penetrates the second insulation portion 170i to electrically connect the plug body portion 184b and the second wiring portion 170. As another example, the contact via of the second plug connecting portion 184f may connect (e.g., directly connect) the landing pad 184p that is disposed on the plug body portion 184b and the second wiring portion 170. However, the present disclosure is not limited thereto. In some embodiments, the second plug connecting portion 184f may connect (e.g., directly connect) the plug body portion 184b and the second wiring portion 170.

In an embodiment, each of the plurality of penetration structures 186 that are included in the capacitor structure 18 (e.g., each of a first penetration structure 1810 and a second penetration structure 1820) may pass through or penetrate the insulation structure 120i, be electrically connected to one of the first wiring portion 160 and the second wiring portion 170 (e.g., a connection wiring portion), and be electrically insulated from the other of the first wiring portion 160 and the second wiring portion 170 (e.g., an insulated wiring portion). In an embodiment, the first wiring portion 160 that includes the bit line 166b and is adjacent to the circuit region 200 may be the connection wiring portion that includes a capacitor wiring (e.g., a first capacitor wiring 1610 and a second capacitor wiring 1620) to which the plurality of penetration structures 186 are electrically connected. The second wiring portion 170 that includes the source wiring layer 176a and is away from the circuit region 200 may be the insulated wiring portion that is electrically insulated from the plurality of penetration structures 186. Accordingly, the first capacitor wiring 1610 and the second capacitor wiring 1620 are included together in the first wiring portion 160 of the connection wiring portion, and may not be included in the second wiring portion 170. For example, the first capacitor wiring 1610 and the second capacitor wiring 1620 may be included together in a first wiring layer 166 that is disposed on the same plane. The first capacitor wiring 1610 and the second capacitor wiring 1620 may be spaced apart from each other in a plan view.

For example, the penetration structure 186 may include a penetration body portion 186b and a first penetration connecting portion 186c. The penetration body portion 186b may pass through or penetrate the insulation structure 120i. The first penetration connecting portion 186e may pass through or penetrate the first insulation portion 160i and connect the penetration body portion 186b and the first wiring portion 160. The penetration structure 186 may not include a second penetration connecting portion that passes through or penetrates the second insulation portion 170i and connects the penetration body portion 186b and the second wiring portion 170. Accordingly, the penetration body portion 186b may be spaced apart from the second wiring portion 170 while interposing the second insulation portion 170i therebetween and be electrically insulated from the second wiring portion 170. In an embodiment, the penetration structure 186 may include one of the first capacitor connecting portion 186e and the second capacitor connecting portion.

The penetration body portion 186b may have a pillar shape. When the plurality of gate stacking portions 121g and 122g are included, the penetration body portion 186b may include a plurality of body portions 1861 and 1862 that are disposed to correspond to the plurality of gate stacking portions 121g and 122g, respectively. For example, when the insulation structure 120i may include or be formed of the sacrificial stacking structure 120s that includes the plurality of insulation stacking portions 121s and 122s, the penetration body portion 186b may include the plurality of body portions 1861 and 1862 that pass through or penetrate the plurality of insulation stacking portions 121s and 122s, respectively. That is, the penetration body portion 186b may have a multi-step via structure that are disposed to correspond to the plurality of gate stacking portions 121g and 122g.

The plurality of body portions 1861 and 1862 of the penetration body portion 186b may overlap each other in a plan view and may be directly connected to each other. Accordingly, an additional intermediate connection wiring configured to connect the plurality of body portions 1861 and 1862 of the penetration body portion 186b in a plan view may be omitted. Accordingly, a structure of the penetration body portion 186b may be simplified.

In an embodiment, it is described as an example that the penetration body portion 186b includes the plurality of body portions 1861 and 1862 that are disposed to correspond to the plurality of gate stacking portions 121g and 122g, respectively, and the penetration body portion 186b entirely passes through or penetrates the insulation structure 120i. Thereby, a capacitance of the capacitor structure 18 may be sufficiently secured. However, the present disclosure is not limited thereto. In some embodiments, the penetration body portion 186b may include a body portion or body portions that correspond to a portion or at least one of the plurality of gate stacking portions 121g and 122g. That is, the penetration body portion 186b may pass through or penetrate a portion of the insulation structure 120i.

In the thickness direction of the semiconductor device 10 (the Z-axis direction), a length of the penetration body portion 186b may be greater than a separation distance H between the penetration body portion 186b and the insulated wiring portion (e.g., the second wiring portion 170). The length of the penetration body portion 186b may refer to a maximum length of the penetration body portion 186b measured in the thickness direction of the semiconductor device 10. The separation distance H may refer to a minimum separation distance between the penetration body portion 186b and the insulated wiring portion or between the landing pad 186p and the insulated wiring portion measured in the thickness direction of the semiconductor device 10. When the penetration body portion 186b has a relatively large length, a capacitance of the capacitor structure 18 may increase.

In a cross-sectional view, each of the plurality of body portions 1861 and 1862 may have an inclined side surface such that a width of each of the body portions 1861 and 1862 gradually decreases toward the second wiring portion 170. A bent portion due to a difference in widths of the plurality of body portions 1861 and 1862 may be provided at a boundary of the plurality of body portions 1861 and 1862. In some embodiments, each of the plurality of body portions 1861 and 1862 may have an inclined side surface that continuously extends without the bent portion, or may have a side surface that extends in the vertical direction. The present disclosure is not limited to a shape of the plurality of body portions 1861 and 1862.

In FIGS. 2 and 5, it is illustrated as an example that the gate stacking structure 120g includes the first and second gate stacking structures 121g and 122g, the insulation structure 120i includes the first and second insulation stacking structures 121s and 122s, and the penetration body portion 186b include first and second body portions 1861 and 1862. However, the present disclosure is not limited thereto. The penetration body portion 186b may include a single body portion or three (3) or more penetration portions.

In an embodiment, a first end of the penetration body portion 186b that is adjacent to the first wiring portion 160 of the connection wiring portion may be an electrical connection end in which the first capacitor connecting portion 186e is provided. An inner end of the penetration structure 186 (e.g., a second end of the penetration body portion 186b) that is disposed at a side of the second wiring portion 170 of the insulated wiring portion and is spaced apart from the second wiring portion 170 may be an insulated end that is surrounded by the second insulation portion 170i. For example, the landing pad 186p that is disposed on the second end of the penetration body portion 186b may be the insulated end that is surrounded by the second insulation portion 170i. In an embodiment, the penetration structure 186 may have a dangling structure in which the inner end of the penetration structure 186 or the second end of the penetration body portion 186b is not connected to the second wiring portion 170 of the insulated wiring portion. A voltage may be applied to the plurality of penetration structures 186 at a side of the first surface 121 of the cell structure 120, but a voltage may not be applied to the plurality of penetration structures 186 at a side of the second surface 122 of the cell structure 120.

The penetration body portion 186b may include a protrusion portion that protrudes than the second surface 122 of the cell structure 120, and a landing pad 186p may be disposed on the protrusion portion of the penetration body portion 186b. The landing pad 186p may be configured to prevent a damage of a preliminary substrate in a process of forming a penetration region for the penetration body portion 186b and stably form the penetration body portion 186b. The landing pad 186p that is included in the penetration body portion 186b and the landing pad 184p that is included in the plug body portion 184b may be formed by the same process or may include or be formed of the same material. However, the present disclosure is not limited thereto. In some embodiments, the landing pad 186p may be omitted.

The first capacitor connecting portion 186e may include a member, a portion, a layer, a via, or the like that passes through or penetrates the first insulation portion 160i to electrically connect the penetration body portion 186b and the first wiring portion 160. For example, the first capacitor connecting portion 186e may include a stud and a contact via. The stud may be electrically connected (e.g., directly connected) to the penetration body portion 186b, and the contact via may be electrically connect (e.g., directly connect) the stud and the first wiring portion 160.

The plug body portion 184b and/or the penetration body portion 186b may be formed by using at least a part of a process of forming the gate contact portion 182. For example, the plug body portion 184b and/or the penetration body portion 186b may have the same structure as the gate contact portion 182, may have the same or similar cross-sectional shape as the gate contact portion 182, and may include or be formed of a material the same as a material of the gate contact portion 182. The plug body portion 184b and/or the penetration body portion 186b may include or be formed of any of various conductive materials. For example, the plug body portion 184b and/or the penetration body portion 186b may include or be formed of a metal material (e.g., tungsten (W), copper (Cu), aluminum (Al), or the like), polycrystalline silicon (Si), metal nitride (e.g., titanium nitride (TiN), tantalum nitride (TaN), tungsten nitride (WN), or the like), or a combination thereof. The plug body portion 184b and/or the penetration body portion 186b may further include a diffusion barrier layer. However, the present disclosure is not limited to a material of the plug body portion 184b and/or the penetration body portion 186b.

The first plug connecting portion 184e and/or the first capacitor connecting portion 186e may be formed by using at least a part of a process of forming the first channel connecting portion C1. For example, the first plug connecting portion 184e and/or the first capacitor connecting portion 186e may have the same structure as the first channel connecting portion C1, may have the same or similar cross-sectional shape as the first channel connecting portion C1, and may include or be formed of a material the same as a material of the first channel connecting portion C1. For example, the first plug connecting portion 184e and/or the first capacitor connecting portion 186e may include the stud and the contact via. The stud of the first plug connecting portion 184e and/or the first capacitor connecting portion 186e may have the same or similar cross-sectional shape as the channel stud C11 of the first channel connecting portion C1 and may include or be formed of a material the same as a material of the channel stud C11 of the first channel connecting portion C1. The contact via of first plug connecting portion 184e and/or the first capacitor connecting portion 186e may have the same or similar cross-sectional shape as the channel contact via C12 of the first channel connecting portion C1, and may include or be formed of a material the same as a material of the channel contact via C12 of the first channel connecting portion C1.

The second plug connecting portion 184f may be formed by using at least a part of a process of forming the second channel connecting portion C2. For example, the second plug connecting portion 184f may have the same structure as the second channel connecting portion C2, may have the same or similar cross-sectional shape as the second channel connecting portion C2, and may include or be formed of a material the same as a material of the second channel connecting portion C2. For example, the second plug connecting portion 184f may include a contact via. The contact via of the second plug connecting portion 184f may have the same or similar cross-sectional shape as the contact via of the second channel connecting portion C2, and may include or be formed of a material the same as of the contact via of the second channel connecting portion C2.

In an embodiment, the penetration structure 186 may not include a connecting portion that corresponds to the second plug connecting portion 184f and/or the second channel connecting portion C2. Thereby, an amount of a conductive material for forming the penetration structure 186 may be reduced. By not forming the connecting portion in a portion in which the penetration structure 186 is disposed in the process of forming the second channel connecting portion C2 and/or the second plug connecting portion 184f, the penetration structure 186 having the above structure may be formed relatively simply, when compared to a related semiconductor device.

That is, in an embodiment, the penetration structure 186 may include a capacitor connecting portion (e.g., the first capacitor connecting portion 186e) that has the same structure as one of the first channel connecting portion C1 and the second channel connecting portion C2 and may not include another capacitor connecting portion (e.g., the second capacitor connecting portion) that corresponds to the other of the first channel connecting portion C1 and the second channel connecting portion C2.

In an embodiment, the plurality of penetration structures 186 may include the first penetration structure 1810 and the second penetration structure 1820. The first penetration structure 1810 may be connected to the first capacitor wiring 1610 and be electrically insulated from the second wiring portion 170 of the insulated wiring portion. The second penetration structure 1820 may be connected to the second capacitor wiring 1620 and be electrically insulated from the second wiring portion 170 of the insulated wiring portion.

For example, one first penetration structure 1810 and a plurality of second penetration structures 1820 that is adjacent to the one first penetration structure 1810 may be spaced apart and electrically insulated from the second wiring portion 170 of the insulated wiring portion. The plurality of second penetration structures 1820 that are adjacent to the one first penetration structure 1810 may be a plurality of second penetration structures 1820 disposed at the shortest distance from the one first penetration structure 1810, or be a plurality of second penetration structures 1820 designed to be disposed at the shortest distance from the one first penetration structures 1810. In FIG. 4, it is illustrated as an example that four (4) second penetration structures 1820 are adjacent to one first penetration structure 1810. However, the present disclosure is not limited thereto. According to an arrangement of the plurality of penetration structures 186, a number of the plurality of second penetration structures 1820 that are adjacent to one first penetration structure 1810 may be two (2), three (3), or five (5), or more. For example, the plurality of second penetration structures 1820 that are adjacent to one first penetration structure 1810 may be 24 or less (e.g., 12 or less), but the present disclosure is not limited thereto.

For example, each of the plurality of penetration structures 186 that are included in the capacitor structure 18 may be electrically connected to the first wiring portion 160 of the connection wiring portion, and be spaced apart and electrically insulated from the second wiring portion 170 of the insulated wiring portion. Thereby, in an entire region of the capacitor structure 18, the capacitor structure 18 may be electrically connected to the first wiring portion 160 of the connection wiring portion, and be electrically insulated from the second wiring portion 170 of the insulated wiring portion. Thereby, the second wiring portion 170 and the plurality of penetration structures 186 may be freely disposed.

In a plan view, the first capacitor wiring 1610 may include a plurality of first extension portions 1612 and a first connection portion 1614. The plurality of first extension portions 1612 may extend parallel to each other at a regular interval, and the first connection portion 1614 may connect the plurality of first extension portions 1612. In a plan view, the second capacitor wiring 1620 may include a plurality of second extension portions 1622 and a second connection portion 1624. The plurality of second extension portions 1622 may extend parallel to each other at a regular interval, and the second connection portion 1624 may connect the plurality of second extension portions 1622. In an extension direction of the first connection portion 1614 or the second connection portion 1624, the first extension portion 1612 and the second extension portion 1622 may be alternately disposed.

In an embodiment, a plurality of first penetration structures 1810 (e.g., a plurality of body structures 186b that are included in the plurality of first penetration structures 1810) may be electrically connected to each first extension portion 1612, and a plurality of second penetration structures 1820 (e.g., a plurality of body structures 186b that are included in the plurality of second penetration structures 1820) may be electrically connected to each second extension portion 1622. For example, the plurality of first penetration structures 1810 may be spaced apart from each other at regular intervals in an extension direction of one first extension portion 1612, and the plurality of second penetration structures 1820 may be spaced apart from each other at regular intervals in an extension direction of one second extension portion 1622. In the extension direction of the first extension portion 1612 or the second extension portion 1622, the second penetration structure 1820 may be disposed between two first penetration structures 1810 that are adjacent to each other, and the first penetration structure 1810 may be disposed between two second penetration structures 1820 that are adjacent to each other. Thereby, a distance between the first penetration structure 1810 and the second penetration structure 1820 may potentially be reduced and thus a number of the plurality of penetration structures 186 may potentially be maximized.

However, the present disclosure is not limited thereto. A shape of the first capacitor wiring 1610 and/or the second capacitor wiring 1620, or a shape, an arrangement, or the like of the first penetration structure 1810 and/or the second penetration structure 1820 may be variously modified. In FIG. 4, it is illustrated as an example that the penetration body portion 186b has a planar shape of a circular shape. However, the present disclosure is not limited thereto. In some embodiments, the penetration body portion 186b may have a planar shape of any of various shapes such as a polygonal shape, an oval shape, a line shape, or the like.

In a plan view, the plurality of penetration structures 186 may overlap the first wiring portion 160 of the connection wiring portion. For example, the first penetration structure 1810 may be disposed in a portion that overlaps the first capacitor wiring 1610, and the second penetration structure 1820 may be disposed in a portion that overlaps the second capacitor wiring 1620. In a direction perpendicular to the first extension portion 1612, a pitch of the plurality of first extension portions 1612 may be the same as a pitch of the plurality of first penetration structures 1810 that are disposed on the plurality of first extension portions 1612. In a direction perpendicular to the second extension portion 1622, a pitch of the plurality of second extension portions 1622 may be the same as a pitch of the plurality of second penetration structures 1820 that are disposed on the plurality of first extension portions 1612. Thereby, an electrical connection structure of the first penetration structure 1810 and the first capacitor wiring 1610 and/or an electrical connection structure of the second penetration structure 1820 and the second capacitor wiring 1620 may be simplified, when compared to a related semiconductor device.

The pitch of the plurality of first extension portions 1612 in the direction perpendicular to the first extension portion 1612 may refer to a distance between centers of two first extension portions 1612 that are adjacent to each other in the direction perpendicular to the first extension portion 1612. The pitch of the plurality of second extension portions 1622 in the direction perpendicular to the second extension portion 1622 may refer to a distance between centers of two second extension portions 1622 that are adjacent to each other in the direction perpendicular to the second extension portion 1622. The pitch of the plurality of first penetration structures 1810 in the direction perpendicular to the first extension portion 1612 may refer to a distance (e.g., a minimum distance) between centers of two first penetration structures 1810 that are adjacent to each other in the direction perpendicular to the first extension portion 1612. The pitch of the plurality of second penetration structures 1820 in the direction perpendicular to the second extension portion 1622 may refer to a distance (e.g., a minimum distance) between centers of two second penetration structures 1820 that are adjacent to each other in the direction perpendicular to the second extension portion 1622.

In an embodiment, in a plan view, at least one of the plurality of penetration structures 186 may be disposed in a portion that does not overlap the second wiring portion 170 of the insulated wiring portion, or a pitch P of the plurality of penetration structures 186 may be different from a pitch of a plurality of wiring portions included in the second wiring portion 170 of the insulated wiring portion in the second region A2. The pitch P of the plurality of penetration structures 186 may refer to a distance (e.g., a minimum distance) between a center of the first penetration structure 1810 and the second penetration structures 1820 that are adjacent to each other. In some embodiments, the pitch P of the plurality of penetration structures 186 may refer to a distance (e.g., a minimum distance) between centers of the first extension portion 1612 and the second extension portion 1622 that are adjacent to each other. The pitch of the plurality of wiring portions may refer to a distance (e.g., a minimum distance) between centers of the plurality of wiring portions.

For example, when the second wiring layer 176 of the second wiring portion 170 includes a plurality of wiring portions 176b in the second region A2, the pitch P of the plurality of penetration structures 186 may be different from a pitch PI of the plurality of wiring portions 176b. The second wiring layer 176 that includes the source wiring layer 176a may have a thickness greater than a thickness of the first wiring layer 166 and thus the plurality of wiring portions 176b may have a relatively large pitch PI. In an embodiment, the second wiring portion 170 that includes the second wiring layer 176 of the relatively large thickness and pith PI may be electrically insulated or separated from the plurality of penetration structures 186. Accordingly, the second wiring portion 170 and the plurality of penetration structures 186 may have various arrangements. That is, the plurality of penetration structures 186 may be freely disposed to enhance properties of the capacitor structure 18, and the second wiring portion 170 may be freely disposed to be suitable to a voltage or signal transmission through the second wiring portion 170. Accordingly, properties of the capacitor structure 18 and properties of the second wiring portion 170 may be enhanced together.

For example, the pitch P of the plurality of penetration structures 186 may be less than the pitch PI of the plurality of wiring portions 176b. Thereby, the capacitance of the capacitor structure 18 may increase. However, the present disclosure is not limited thereto. In some embodiments, the pitch P of the plurality of penetration structures 186 may be the same or greater than the pitch PI of the plurality of wiring portions 176b.

The pitch P of the plurality of penetration structures 186 may be less than the separation distance H between the penetration body portion 186b and the insulated wiring portion in the thickness direction of the semiconductor device 10 (the Z-axis direction). Thereby, the pitch P of the plurality of penetration structures 186 may be reduced and thus the capacitance may increase. However, the present disclosure is not limited thereto. In some embodiments, in a plan view, the pitch P of the plurality of penetration structures 186 may be the same as or greater than the separation distance H between the penetration body portion 186b and the insulated wiring portion in the thickness direction of the semiconductor device 10 (the Z-axis direction).

For example, in a plan view, the pitch P of the plurality of penetration structures 186 may be less than a pitch of the plurality of gate contact portions 182. The pitch of the plurality of gate contact portions 182 may refer to a distance (e.g., a minimum distance) between two gate contact portions 182 that are adjacent to each other. Thereby, the pitch P of the plurality of penetration structures 186 may be reduced and thus the capacitance may increase. However, the present disclosure is not limited thereto. In some embodiments, the pitch P of the plurality of penetration structures 186 may be the same as or greater than the pitch of the plurality of gate contact portions 182.

For example, in a plan view, a width of the penetration structure 186 may be greater than a width of the gate contact portion 182. The width of the gate contact portion 182 may refer to a maximum width of the gate contact portion 182, and the width of the penetration structure 186 may refer to a maximum width of the penetration structure 186. The width of the penetration structure 186 may increase in a state that the pitch P of the plurality of penetration structures 186 may be maintained, thereby increasing the capacitance. However, the present disclosure is not limited thereto. In some embodiments, the width of the penetration structure 186 may be the same as or less than the width of the gate contact portion 182.

In a comparative example in which a plurality of penetration structures are connected to in both of first and second wiring portions, each of the first and second wiring portions may include capacitor wirings. Since a pitch of the penetration structures and a pitch of capacitor wirings may be the same, the pitch of the penetration structures and a pitch of capacitor wirings included in the first wiring portion may be the same, and the pitch of the penetration structures and a pitch of capacitor wiring included in the second wiring portion may be the same. The second wiring portion may have a relatively large thickness and thus may have a relatively large pitch. Accordingly, when the thickness of the second wiring portion is increased to improve electrical resistance of the second wiring portion, there is a limit to reducing the pitch of the penetration structures. When the pitch of the penetration structures is reduced to potentially improve a capacitance of a capacitor structure, the second wiring layer may not have a sufficient thickness. Accordingly, it may be difficult to improve properties of the capacitor structure and properties of the second wiring portion together.

An example of a manufacturing of a semiconductor device 10, according to an embodiment, is described.

A plurality of insulation stacking portions 121s and 122s of a sacrificial stacking structure 120s may be formed on a preliminary substrate, and penetration regions for a channel body portion CB, a gate contact portion 182, a plug body portion 184b, and a penetration body portion 186b may be formed in the sacrificial stacking structure 120s. The plurality of insulation stacking portions 121s and 122s may have a stair shape in a connection region A12.

In the penetration region configured to form the channel body portion CB, a channel layer 140, a gate dielectric layer 150, a core insulation layer 142, a channel pad 144, or the like may be formed to from the channel body portion CB. A penetration opening may be formed in a portion of the sacrificial stacking structure 120s that corresponds to a separation structure 146. The sacrificial insulation layers 130s that are disposed in at least a portion of a first region A1 are selectively removed by using the penetration opening and gate electrodes 130 are formed in portions in which the sacrificial insulation layers 130s are removed to form a gate stacking structure 120g. At least a conductive material may be filled in the penetration regions configured to form the plug body portion 184b and the penetration body portion 186b to form the plug body portion 184b and the penetration body portion 186b.

A first insulation portion 160i may be formed, a first channel connecting portion C1, a first plug connecting portion 184c, and a first capacitor connecting portion 186e that pass through or penetrate the first insulation portion 160i are formed, and a first wiring portion 160 may be formed. Thereby, a preliminary cell region may be formed.

The preliminary cell region may be bonded to a circuit region 200, and the preliminary substrate and the gate dielectric layer 150 that is disposed on a protrusion portion CHP of the channel body portion CB may be removed. A horizontal conductive portion 112 may be formed on the protrusion portion CHP of the channel body portion CB. A second insulation portion 170i may be formed, a second channel connecting portion C2 and a second plug connecting portion 184f that pass through or penetrate the second insulation portion 170i may be formed, and a second wiring portion 170 may be formed. Thereby, a semiconductor device 10 may be formed.

In the semiconductor device 10, according to an embodiment, the capacitor structure 18 may have a vertical capacitor that include the plurality of penetration structures 186, and each of the plurality of penetration structures 186 may have a vertical structure that extends in the vertical direction of the semiconductor device 10. Thus, the capacitor structure 18 may have a relatively large capacitance in a relatively small area. The plurality of penetration structures 186 may be electrically connected to one (e.g., the connection wiring portion) of the first and second wiring portions 160 and 170 and may be electrically insulated from the other (e.g., the insulated wiring portion) of the first and second wiring portions 160 and 170. Thus, the plurality of penetration structures 186 and the insulated wiring portion may be freely disposed. Accordingly, properties of the capacitor structure 18 and properties of the insulated wiring portion may potentially be enhanced and thus performance of the semiconductor device 10 may potentially be enhanced, when compared to a related semiconductor device. For example, by reducing a pitch P of the plurality of penetration structures 186, the capacitance may be effectively increased, and thus, a data processing speed of the semiconductor device 10 may be enhanced. As another example, by increasing the thickness of the second wiring layer 176 that includes the source wiring layer 176a, electrical resistance of the source wiring layer 176a may be reduced.

In an embodiment, it is described or illustrated as an example that the capacitor structure 18 is disposed in the outer region 12 outside the memory region 10m. Thereby, the capacitor structure 18 may be disposed in the outer region 12 and thus the outer region 12 may be suitably used. However, the present disclosure is not limited thereto. Accordingly, the capacitor structure 18 may be disposed in an inner portion of the memory region 10m (e.g., the cell array region A11 and/or the connection region A12).

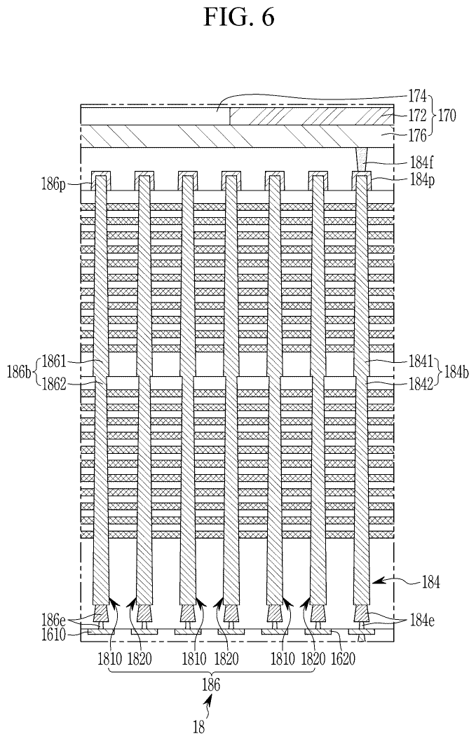

In the above description, it is described as an example that, in one capacitor structure 18, the first wiring portion 160 is the connection wiring portion and the second wiring portion 170 is the insulated wiring portion. In another capacitor structure, the second wiring portion 170 may be the connection wiring portion and the first wiring portion 160 may be the insulated wiring portion. That is, a first capacitor structure where the first wiring portion 160 is the connection wiring portion and the second wiring portion 170 is the insulated wiring portion and a second capacitor structure where the second wiring portion 170 is the connection wiring portion and the first wiring portion 160 is the insulated wiring portion may be included together. Thereby, the capacitor structure 18, the first wiring portion 160, and the second wiring portion 170 may be freely disposed. This may be applied to embodiments and modified embodiments described with reference to FIGS. 6 to 11.

Hereinafter, referring to FIGS. 6 to 11, semiconductor devices, according to modified embodiments, and embodiments are further described. To the extent that an element is not described in detail below, it may be understood that the element is at least substantially similar to (and/or the same as) a corresponding element that has been described elsewhere within the present disclosure.

FIG. 6 is a partial cross-sectional view that illustrates a capacitor structure, a penetrating plug, and first and second wiring portions included in a semiconductor device, according to a modified embodiment. FIG. 6 is a cross-sectional view that corresponds to FIG. 5.

Referring to FIG. 6, in a portion of a second region (e.g., a portion in which a capacitor structure 18 is disposed), a second wiring layer 176 (e.g., the second wiring layer 176 that includes a source wiring layer) of a second wiring layer 176 may include or be formed of a single portion. When the portion of the second region (e.g., the portion in which the capacitor structure 18 is disposed) includes or is formed of the single portion, the portion of the second region may be regarded to have a pitch different from a pitch (e.g., a uniform pitch) of a plurality of penetration structures 186. In an embodiment, in the second region, the second wiring layer 176 may have a sufficient arca.

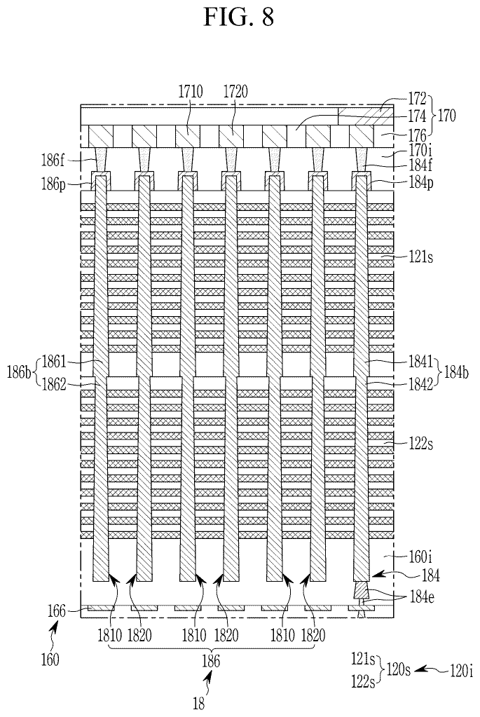

In FIG. 6, it is illustrated as an example that the penetration structure 186 has a shape illustrated in FIG. 5, but the present disclosure is not limited thereto. The penetration structure 186 may have a shape illustrated in FIG. 8, and other various modifications are possible. In FIG. 6, it is illustrated as an example that an insulation structure has a structure illustrated in FIG. 5, but the present disclosure is not limited thereto. The insulation structure may have a structure illustrated in FIG. 11, and other various modifications are possible.

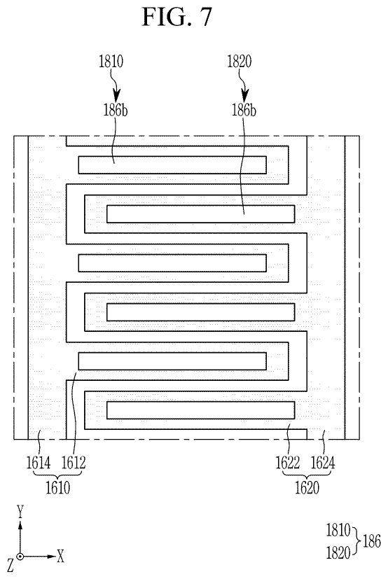

FIG. 7 is a partial plan view that illustrates a capacitor structure included in a semiconductor device, according to an embodiment. FIG. 7 illustrates a portion that corresponds to FIG. 4. In FIG. 7, a penetration body portion 186b of a penetration structure 186 is mainly illustrated and a first capacitor connecting portion may be omitted.

Referring to FIG. 7, in an embodiment, a plurality of penetration structures 186 (e.g., each of a first penetration structure 1810 and a second penetration structure 1820) may pass through or penetrate an insulation structure, be electrically connected to a first wiring portion, and be electrically insulated from a second wiring portion. The first wiring portion that includes a bit line and is adjacent to a circuit region may be a connection wiring portion that includes a first capacitor wiring 1610 and a second capacitor wiring 1620, and a second wiring portion that includes a source wiring layer and is away from the circuit region may be an insulated wiring portion that is electrically insulated from the plurality of penetration structures 186. The description with reference to FIGS. 1 to 6 may be applied thereto.

In an embodiment, in a plan view, a first penetration structure 1810 that has an extended shape extending in an extension direction of a first extension portion 1612 may be connected to each first extension portion 1612, and a second penetration structure 1820 that has an extended shape extending in an extension direction of a second extension portion 1622 may be connected to each second extension portion 1622.

For example, in a plan view, a penetration body portion 186b of the first penetration structure 1810 may have an extended shape that longitudinally extends in the extension direction of the first extension portion 1612, and a penetration body portion 186b of the second penetration structure 1820 may have an extended shape that longitudinally extends in the extension direction of the second extension portion 1622. Thereby, the penetration body portion 186b of the first penetration structure 1810 and/or the second penetration structure 1820 may be a barrier rib shape or a wall type. The penetration body portion 186b of the first penetration structure 1810 and/or the second penetration structure 1820 may have a sufficient area and thus a capacitance of a capacitor structure may potentially be enhanced, when compared to a related semiconductor device.

When a plurality of gate stacking portions are included, the penetration body portion 186b may include a plurality of body portions that are disposed to correspond to the plurality of gate stacking portions, respectively. In a cross-sectional view that perpendicular to an extension direction of the first extension portion 1612 or the second extension portion 1622, each of the plurality of body portions may have an inclined side surface such that a width of each of the body portions gradually decreases toward the second wiring portion due to an aspect ratio. A bent portion due to a difference in widths of the plurality of body portions may be provided at a boundary of the body portions. In some embodiments, each of the plurality of body portions may have an inclined side surface that continuously extends without the bent portion, or may have a side surface that extends in a vertical direction. The present disclosure is not limited to a shape of the plurality of body portions.

In FIG. 7, it is illustrated as an example that one penetration body portion 186b may be disposed on one first extension portion 1612 and one penetration body portion 186b may be disposed on one second extension portion 1622. Thereby, a planar area of the penetration body portion 186b may be maximized and thus a capacitance of the capacitor structure may be maximized. However, the present disclosure is not limited thereto. A plurality of penetration body portions 186b, each having the extended shape extending in the extension direction, the barrier rib shape, or the wall type, may be disposed on one first extension portion 1612 or one second extension portion 1622.

For example, at least a portion (e.g., a stud and/or a contact via) of a first capacitor connecting portion of the penetration structure 186 may have an extended shape that longitudinally extends in the extension direction to correspond to the first or second extension portion 1612 or 1622. Thereby, a planar area of the first capacitor connecting portion may increase and thus a capacitance of the capacitor structure may increase. In such a case, in a cross-sectional view perpendicular to the extension direction of the first or second extension portion 1612 or 1622, at least the portion (e.g., the stud and/or the contact via) of the first capacitor connecting portion may have a structure or a cross-sectional shape the same as or similar to a structure or a cross-sectional shape of a first channel connecting portion and/or a first plug connecting portion.

In some embodiments, at least a portion (e.g., a stud and/or a contact via) of a first capacitor connecting portion of the first penetration structure 1810 may be included in plural to be spaced apart from each other at regular intervals in the extension direction of the first or second extension portion 1612 or 1622. In such a case, at least the portion (e.g., the stud and/or the contact via) of the first capacitor connecting portion may have a structure or a cross-sectional shape the same as or similar to the structure or the cross-sectional shape of the first channel connecting portion and/or the first plug connecting portion. Thereby, the first capacitor connecting portion may have a size the same as or similar to a size of the first channel connecting portion and/or the first plug connecting portion and thus a manufacturing process may be simplified, when compared to related semiconductor devices.

In an embodiment, the penetration structure 186 may not include a second capacitor connecting portion that corresponds to a second channel connecting portion and/or a second plug connecting portion passing through or penetrating a second insulation portion.

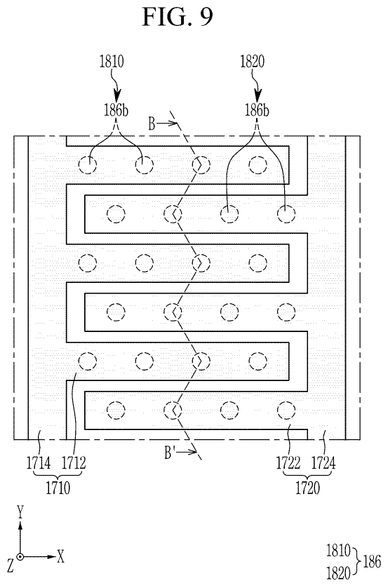

FIG. 8 is a partial cross-sectional view that illustrates a capacitor structure, a penetrating plug, and first and second wiring portions included in a semiconductor device, according to an embodiment. FIG. 9 is a partial plan view that illustrates the capacitor structure illustrated in FIG. 8. A cross-sectional view of the capacitor structure taken along a line B-B′ in FIG. 9 is illustrated in FIG. 8.

Referring to FIGS. 8 and 9, in an embodiment, a plurality of penetration structures 186 (e.g., each of a first penetration structure 1810 and a second penetration structure 1820) may pass through or penetrate an insulation structure 120i, be electrically connected to a second wiring portion 170, and be electrically insulated from a first wiring portion 160. Thereby, the first wiring portion 160 and the plurality of penetration structures 186 may be freely disposed.

In an embodiment, the first wiring portion 160 that includes a bit line and is adjacent to a circuit region may be an insulated wiring portion that is electrically insulated from the plurality of penetration structures 186, and the second wiring portion 170 that includes a source wiring layer and is away from the circuit region may be a connection wiring portion that includes a first capacitor wiring 1710 and a second capacitor wiring 1720. Accordingly, the first capacitor wiring 1710 and the second capacitor wiring 1720 are included together in the second wiring portion 170 of the connection wiring portion, and may not be included in the first wiring portion 160. For example, the first capacitor wiring 1710 and the second capacitor wiring 1720 may be included together in a second wiring layer 176 that is disposed on the same plane. The first capacitor wiring 1710 and the second capacitor wiring 1720 may be spaced apart from each other in a plan view.

For example, the penetration structure 186 may include a penetration body portion 186b and a second penetration connecting portion 186f. The penetration body portion 186b may pass through or penetrate the insulation structure 120i. The second penetration connecting portion 186f may pass through or penetrate a second insulation portion 170i and connect the penetration body portion 186b and the second wiring portion 170. The penetration structure 186 may not include a first penetration connecting portion that passes through or penetrates a first insulation portion 160i and connects the penetration body portion 186b and the first wiring portion 160. Accordingly, the penetration body portion 186b may be spaced apart from the first wiring portion 160 while interposing the first insulation portion 160i therebetween and be electrically insulated from the first wiring portion 160. In an embodiment, the penetration structure 186 may include one of the first capacitor connecting portion and the second capacitor connecting portion 186f.

In an embodiment, a second end of the penetration body portion 186b that is adjacent to the second wiring portion 170 of the connection wiring portion may be an electrical connection end in which the second capacitor connecting portion 186f is provided. An inner end of the penetration structure 186 (e.g., a first end of the penetration body portion 186b) that is disposed at a side of the first wiring portion 160 of the insulated wiring portion and is spaced apart from the first wiring portion 160 may be an insulated end that is surrounded by the first insulation portion 160i. In an embodiment, the penetration structure 186 may have a dangling structure in which the inner end of the penetration structure 186 or the first end of the penetration body portion 186b is not connected to the first wiring portion 160 of the insulated wiring portion. A voltage may be applied to the plurality of penetration structures 186 at a side of a second surface 122 of a cell structure 120, but a voltage may not be applied to the plurality of penetration structures 186 at a side of a first surface 121 of the cell structure 120.

A second capacitor connecting portion 186f may include a member, a portion, a layer, a via, or the like that passes through or penetrates the second insulation portion 170i to electrically connect the penetration body portion 186b and the second wiring portion 170. For example, the second capacitor connecting portion 186f may include a contact via that connects (e.g., directly connects) the penetration body portion 186b and the second wiring portion 170.

A second plug connecting portion 184f and/or the second capacitor connecting portion 186f may be formed by using at least a part of a process of forming a second channel connecting portion C2. For example, the second plug connecting portion 184f and/or the second capacitor connecting portion 186f may have the same structure as a second channel connecting portion C2, may have the same or similar cross-sectional shape as the second channel connecting portion C2, and may include or be formed of a material the same as a material of the second channel connecting portion C2. For example, the second plug connecting portion 184f and/or the second capacitor connecting portion 186f may include a contact via. For example, the contact via of the second plug connecting portion 184f and/or the second capacitor connecting portion 186f may have the same structure as a contact via of the second channel connecting portion C2, may have the same or similar cross-sectional shape as the contact via of the second channel connecting portion C2, and may include or be formed of a material the same as a material of the contact via of the second channel connecting portion C2.

In an embodiment, the penetration structure 186 may not include a connecting portion that corresponds to a first plug connecting portion 184c and/or a first channel connecting portion C1. Thereby, an amount of a conductive material for forming the penetration structure 186 may be reduced. By not forming a connecting portion in a portion in which the penetration structure 186 is disposed in a process of forming the first channel connecting portion C1 and/or the first plug connecting portion 184c, the penetration structure 186 having the above structure may be easily formed.

That is, in an embodiment, the penetration structure 186 may include a capacitor connecting portion (e.g., the second capacitor connecting portion 186f) that may have the same structure as one of the first channel connecting portion C1 and the second channel connecting portion C2 and may not include another capacitor connecting portion (e.g., the first capacitor connecting portion) that corresponds to the other of the first channel connecting portion C1 and the second channel connecting portion C2.

In a plan view, the first capacitor wiring 1710 may include a plurality of first extension portions 1712 and a first connection portion 1714. The plurality of first extension portions 1712 may extend parallel to each other at a regular interval, and the first connection portion 1714 may connect the plurality of first extension portions 1712. In a plan view, the second capacitor wiring 1720 may include a plurality of second extension portions 1722 and a second connection portion 1724. The plurality of second extension portions 1722 may extend parallel to each other at a regular interval, and the second connection portion 1724 may connect the plurality of second extension portions 1722. In an extension direction of the first connection portion 1714 or the second connection portion 1724, the first extension portion 1712 and the second extension portion 1722 may be alternately disposed.

In an embodiment, a plurality of first penetration structures 1810 (e.g., a plurality of body structures 186b that are included in the plurality of first penetration structures 1810) may be electrically connected to each first extension portion 1712, and a plurality of second penetration structures 1820 (e.g., a plurality of body structures 186b that are included in the plurality of second penetration structures 1820) may be electrically connected to each second extension portion 1722. For example, the plurality of first penetration structures 1810 may be spaced apart from each other at regular intervals in the extension direction of one first extension portion 1712, and the plurality of second penetration structures 1820 may be spaced apart from each other at regular intervals in the extension direction of one second extension portion 1722. In the extension direction of the first extension portion 1712 or the second extension portion 1722, the second penetration structure 1820 may be disposed between two first penetration structures 1810 that are adjacent to each other, and the first penetration structure 1810 may be disposed between two second penetration structures 1820 that are adjacent to each other. Thereby, a distance between the first penetration structure 1810 and the second penetration structure 1820 may be reduced and thus a number of the plurality of penetration structures 186 may be maximized.

However, the present disclosure is not limited thereto. A shape of the first capacitor wiring 1710 and/or the second capacitor wiring 1720, or a shape, an arrangement, or the like of the first penetration structure 1810 and/or the second penetration structure 1820 may be variously modified.

In a plan view, the plurality of penetration structures 186 may overlap the second wiring portion 170 of the connection wiring portion. For example, the first penetration structure 1810 may be disposed in a portion that overlaps the first capacitor wiring 1710, and the second penetration structure 1820 may be disposed in a portion that overlaps the second capacitor wiring 1720. In a direction perpendicular to the first extension portion 1712, a pitch of the plurality of first extension portions 1712 may be the same as a pitch of the plurality of first penetration structures 1810 that are disposed on the plurality of first extension portions 1712. In a direction perpendicular to the second extension portion 1722, a pitch of the plurality of second extension portions 1722 may be the same as a pitch of the plurality of second penetration structures 1820 that are disposed on the plurality of first extension portions 1712. Thereby, an electrical connection structure of the first penetration structure 1810 and the first capacitor wiring 1710 and/or an electrical connection structure of the second penetration structure 1820 and the second capacitor wiring 1720 may be simplified.

A description of a shape, an arrangement, or the like of a first capacitor wiring 1610, a second capacitor wiring 1620, a first penetration structure 1810, and/or a second penetration structure 1820 with reference to FIGS. 1 to 5 may be applied to a shape, an arrangement, or the like of the first capacitor wiring 1710, the second capacitor wiring 1720, the first penetration structure 1810, and/or the second penetration structure 1820.

In an embodiment, in a plan view, at least one of the plurality of penetration structures 186 may be disposed in a portion that does not overlap the first wiring portion 160 of the insulated wiring portion, or the pitch of the plurality of penetration structures 186 may be different from a pitch of a plurality of wiring portions included in the first wiring portion 160 of the insulated wiring portion in a second region.

For example, when a first wiring layer 166 of the first wiring portion 160 includes a plurality of wiring portions, the pitch of the plurality of penetration structures 186 may be different from a pitch of the plurality of wiring portions of the first wiring portion 166 in a second region. For example, the pitch of the plurality of penetration structures 186 may be less than the pitch of the plurality of wiring portions. Thereby, a capacitance of the capacitor structure 18 may increase. However, the present disclosure is not limited thereto. In some embodiments, the pitch of the plurality of penetration structures 186 may be the same or greater than the pitch of the plurality of wiring portions.

In an embodiment, the first wiring portion 160 may be electrically insulated or separated from the plurality of penetration structures 186. Accordingly, the first wiring portion 160 and the plurality of penetration structures 186 may have various arrangements. That is, the plurality of penetration structures 186 may be freely disposed to enhance properties of the capacitor structure 18, and the first wiring portion 160 may be freely disposed to be suitable to the first wiring portion 160. Accordingly, properties of the capacitor structure 18 and properties of the first wiring portion 160 may be enhanced together. A second wiring layer 176 that has a relatively large thickness may constitute a part of the capacitor structure 18, together with the plurality of penetration structures 186, and thus a capacitance of the capacitor structure 18 be effectively enhanced. Accordingly, performance of the semiconductor device 10 may potentially be enhanced, when compared to a related semiconductor device.

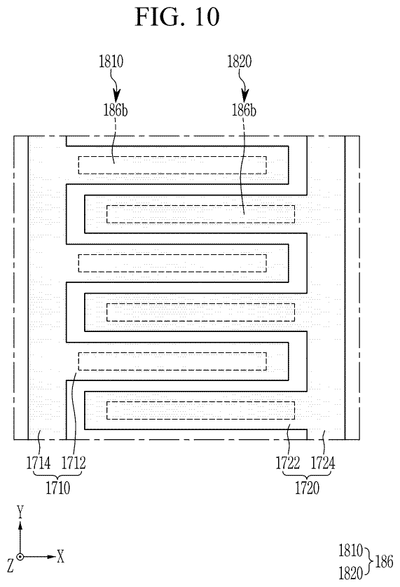

FIG. 10 is a partial plan view that illustrates a capacitor structure included in a semiconductor device, according to an embodiment. FIG. 10 illustrates a portion that corresponds to FIG. 9. In FIG. 10, a penetration body portion 186b of a penetration structure 186 is mainly illustrated and a second capacitor connecting portion is omitted.

Referring to FIG. 10, in an embodiment, a plurality of penetration structures 186 (e.g., each of a first penetration structure 1810 and a second penetration structure 1820) may pass through or penetrate an insulation structure, be electrically connected to a second wiring portion, and be electrically insulated from a first wiring portion. The first wiring portion that includes a bit line and is adjacent to a circuit region may be an insulated wiring portion that is electrically insulated from the plurality of penetration structures 186, and a second wiring portion that includes a source wiring layer and is away from the circuit region may be a connection wiring portion that includes a first capacitor wiring 1710 and a second capacitor wiring 1720. The description with reference to FIGS. 8 and 9 may be applied thereto.

In an embodiment, in a plan view, a first penetration structure 1810 that has an extended shape extending in an extension direction of a first extension portion 1712 may be connected to each first extension portion 1712, and a second penetration structure 1820 that has an extended shape extending in an extension direction of a second extension portion 1722 may be connected to each second extension portion 1722.

For example, in a plan view, a penetration body portion 186b of the first penetration structure 1810 may have an extended shape that longitudinally extends in the extension direction of the first extension portion 1712, and a penetration body portion 186b of the second penetration structure 1820 may have an extended shape that longitudinally extends in the extension direction of the second extension portion 1722. Thereby, the penetration body portion 186b of the first penetration structure 1810 and/or the second penetration structure 1820 may be a barrier rib shape or a wall type. The penetration body portion 186b of the first penetration structure 1810 and/or the second penetration structure 1820 may have a sufficient area and thus a capacitance of a capacitor structure may potentially be enhanced, when compared to a related semiconductor device.

A description of a shape of a penetration body portion 186b of a first penetration structure 1810 and/or a second penetration structure 1820 with reference to FIG. 7 may be applied to a shape of the penetration body portion 186b of the first penetration structure 1810 and/or the second penetration structure 1820.

For example, at least a portion (e.g., a contact via) of a second capacitor connecting portion of the penetration structure 186 may have an extended shape that longitudinally extends in the extension direction to correspond to the first or second extension portion 1712 or 1722. Thereby, a planar area of the second capacitor connecting portion may increase and thus a capacitance of the capacitor structure may increase. In such a case, in a cross-sectional view perpendicular to the extension direction of the first or second extension portion 1712 or 1722, at least the portion (e.g., the contact via) of the second capacitor connecting portion may have a structure or a cross-sectional shape the same as or similar to a structure or a cross-sectional shape a second channel connecting portion and/or a second plug connecting portion.

In some embodiments, at least a portion (e.g., a contact via) of a second capacitor connecting portion of the first penetration structure 1810 may be included in plural to be spaced apart from each other at regular intervals in the extension direction of the first or second extension portion 1712 or 1722. In such a case, at least the portion (e.g., the contact via) of the second capacitor connecting portion may have a structure or a cross-sectional shape the same as or similar to a structure or a cross-sectional shape of the second channel connecting portion and/or the second plug connecting portion. Thereby, the second capacitor connecting portion may have a size the same as or similar to a size of the second channel connecting portion and/or the second plug connecting portion and thus a manufacturing process may be simplified, when compared to a related semiconductor device.

In an embodiment, the penetration structure 186 may not include a first capacitor connecting portion that corresponds to a first channel connecting portion and/or a first plug connecting portion passing through or penetrating a first insulation portion 160i.

FIG. 11 is a partial cross-sectional view that illustrates a capacitor structure, a penetrating plug, and first and second wiring portions included in a semiconductor device, according to a modified embodiment. FIG. 11 illustrates a portion that corresponds to FIG. 5.

Referring to FIG. 11, in an embodiment, an insulation structure 120i may include or be formed of a single insulating material. A sacrificial stacking structure (e.g., sacrificial stacking structure 120s of FIG. 2) may be formed in a first region and a second region, a plurality of sacrificial insulation layers 130s of the sacrificial stacking structure 120s in the first region may be replaced with a plurality of gate electrodes 130 to form a gate stacking structure (e.g., gate stacking structure 120g of FIG. 2), the sacrificial stacking structure 120s in the second region may be removed, and a single insulating material may be formed to form the insulation structure 120i.

The insulation structure 120i may be disposed to correspond to the gate stacking structure 120g in a thickness direction of a semiconductor device 10 (a Z-axis direction).

The insulation structure 120i may include or be formed of any of various insulating materials. For example, the insulation structure 120i may include or be formed of silicon oxide (SiO₂), silicon nitride (Si₃N₄), silicon oxynitride (SiOₓN_{y}), a low dielectric constant material that has a lower dielectric constant than silicon oxide (SiO₂), or a combination thereof.

When a plurality of gate stacking portions (e.g., first and second gate stacking portions 121g and 122g of FIG. 2) are included, a penetration body portion 186b may include a plurality of body portions 1861 and 1862 that are disposed to correspond to the plurality of gate stacking portions 121g and 122g, respectively.

For the sake of description, FIG. 11 illustrates a boundary line between the insulation structure 120i and a first insulation portion 160i as a dotted line. The boundary line between the insulation structure 120i and the first insulation portion 160i may be seen or identified or may not be seen or identified.

In the above, it is described as an example that the gate stacking structure 120g includes the plurality of gate stacking portions and the insulation structure 120i includes a single portion including or being formed of a single material, but the present disclosure is not limited thereto. In some embodiments, the gate stacking structure 120g may include a plurality of gate stacking portions, and the insulation structure 120i may include a plurality of portions, each having a single material. A boundary of the plurality of portions of the insulation structure 120i may be seen or identified or may not be seen or identified.

In FIG. 11, it is illustrated as an example that the penetration structure 186 has a shape illustrated in FIG. 5, but the present disclosure is not limited thereto. The penetration structure 186 may have a shape illustrated in FIG. 6 or FIG. 8, and other various modifications may be possible.

Hereinafter, an example of an electronic system that includes a semiconductor device described above is described.

FIG. 12 schematically illustrates an electronic system that includes a semiconductor device, according to an embodiment.

Referring to FIG. 12, an electronic system 1000, according to an embodiment, may include a semiconductor device 1100 and a controller 1200 that is electrically connected to the semiconductor device 1100. The electronic system 1000 may be and/or may include a storage device that includes one or a plurality of semiconductor devices 1100 or an electronic device that includes the storage device. For example, the electronic system 1000 may be and/or may include a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIGS. 1 to 11. The semiconductor device 1100 may include a first structure 1100F and a second structure 1100S that is disposed on the first structure 1100F. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, gate upper lines (e.g., a first gate upper line UL1 and a second gate upper line UL2), gate lower lines (e.g., a first gate lower line LL1 and a second gate lower line LL2), and a memory cell string CSTR between the bit line BL and the common source line CSL.

In the second structure 1100S, each of memory cell strings CSTR may include lower transistors (e.g., a first lower transistor LT1 and a second lower transistor LT2) that are adjacent to the common source line CSL, upper transistors (e.g., a first upper transistor UT1 and a second upper transistor UT2) that are adjacent to the bit line BL, and a plurality of memory cell transistors MCT between the first and second lower transistors LT1 and LT2 and the first and second upper transistors UT1 and UT2. A number of the first and second lower transistors LT1 and LT2 and a number of the upper transistors first and second UT1 and UT2 may be variously modified, according to an embodiment.

In an embodiment, the first or second lower transistor LT1 or LT2 may include a ground selection transistor, and the first or second upper transistor UT1 or UT2 may include a string selection transistor. The first and second gate lower lines LL1 and LL2 may be gate electrodes of the first and second lower transistors LT1 and LT2, respectively. The word line WL may be a gate electrode of the memory cell transistor MCT, and the first and second gate upper lines UL1 and UL2 may be gate electrodes of the first and second upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

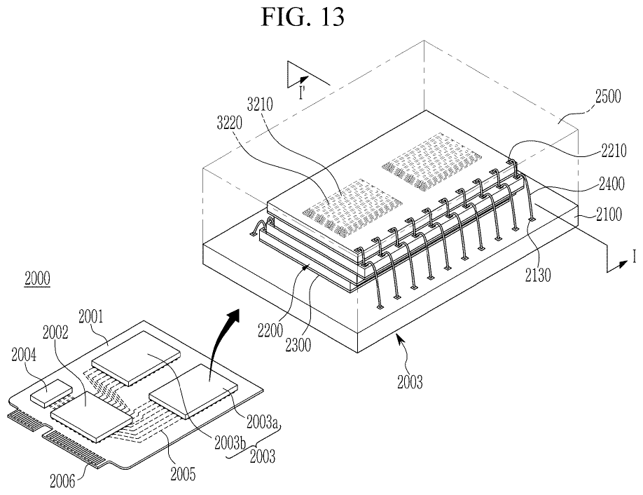

FIG. 13 is a perspective view that schematically illustrates an electronic system including a semiconductor device, according to an embodiment.

Referring to FIG. 13, an electronic system 2000, according to an embodiment, may include a main substrate 2001, a controller 2002 that is mounted on the main substrate 2001, one or more semiconductor packages 2003, and a dynamic random access memory (DRAM) 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In an embodiment, the electronic system 2000 may communicate with the external host according to any one of interfaces such as, but not limited to, a universal serial bus (USB), a peripheral component interconnect express (PCI-Express), a serial advanced technology attachment (SATA), or an M-Phy for a universal flash storage (UFS). In an embodiment, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also perform functions related to a cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b that may be spaced apart from each other. Each of the first and second semiconductor packages 2003a and 2003b may include a package substrate 2100, the semiconductor chip 2200 that is disposed on the package substrate 2100, an adhesive layer 2300 at a lower surface of each semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 may be a printed circuit board that includes a package upper pad 2130. Each semiconductor chip 2200 may include an input/output pad 2210. The input/output pad 2210 may correspond to an input/output pad 1101 of FIG. 12. Each semiconductor chip 2200 may include a gate stacking structure 4210 and a channel structure 4220. The semiconductor chip 2200 may include the semiconductor device described with reference to FIGS. 1 to 11.

In an embodiment, the connection structure 2400 may be a bonding wire that electrically connects the input/output pad 2210 and the package upper pad 2130. Accordingly, in each of the first and second semiconductor packages 2003a and 2003b, the semiconductor chips 2200 may be electrically connected to each other using a bonding wire type, and the semiconductor chip 2200 may be electrically connected to the package upper pad 2130 of the package substrate 2100. According to an embodiment, in each of the first and second semiconductor packages 2003a and 2003b, the semiconductor chips 2200 may be electrically connected to each other by a connection structure that includes a through silicon via (TSV) instead of the connection structure 2400 of the bonding wire type.

In an embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to each other by a wiring of the interposer substrate.

FIG. 14 is a cross-sectional view that schematically illustrates a semiconductor package, according to an embodiment. FIG. 14 illustrates an embodiment of the semiconductor package 2003 of FIG. 13, and conceptually illustrates a region of the semiconductor package 2003 taken along a line I-I′ in FIG. 13.

Referring to FIG. 14, in a semiconductor package 2003, a package substrate 2100 may be a printed circuit board. The package substrate 2100 may include a package substrate body portion 2120, a package upper pad 2130 that is disposed at an upper surface of the package substrate body portion 2120, a package lower pad 2125 that is disposed at a lower surface of the package substrate body portion 2120 or is exposed through the lower surface of the package substrate body portion 2120, and an internal wiring 2135 that electrically connects the package upper pad 2130 and the package lower pad 2125 inside the package substrate body portion 2120. The package upper pad 2130 may be electrically connected to the connection structure 2400. The package lower pad 2125 may be connected to a wiring pattern 2005 of a main substrate 2001 of an electronic system 2000, as illustrated in FIG. 13, through a conductive connection portion 2600.

In a semiconductor package 2003, each semiconductor chip 2200 may include a semiconductor substrate 4010, a first structure 4100 that is disposed on the semiconductor substrate 4010, and a second structure 4200 that is disposed on the first structure 4100 and is bonded to the first structure 4100 by a wafer bonding type.

The first structure 4100 may include a peripheral circuit region that includes a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 that pass through the gate stacking structure 4210, and a second bonding structures 4250 that are electrically connected to the channel structure 4220 and a word line (e.g., word line WL of FIG. 12) of the gate stacking structure 4210. For example, the second bonding structure 4250 may be electrically connected to the channel structure 4220 and the word line WL through a bit line 4240 that is electrically connected to the channel structure 4220 and a gate connection wiring that is electrically connected to the word line WL. The first bonding structure 4150 of the first structure 4100 and the second bonding structure 4250 of the second structure 4200 may be in contact with and bonded to each other. For example, portions of the first bonding structure 4150 and the second bonding structure 4250 where the first bonding structure 4150 and the second bonding structure 4250 are bonded may include copper (Cu).

In an embodiment, the semiconductor chip 2200 or a semiconductor device may include a capacitor structure 18 that includes a plurality of penetration structures 186, each passing through or penetrating an insulation structure that is disposed to correspond to the gate stacking structure 4210. The plurality of penetration structures 186 may be electrically connected to a connection wiring portion that is one of first and second wiring portions 160 and 170, and may be electrically insulated from an insulated wiring portion that is the other of the first and second wiring portions 160 and 170. Thereby, the plurality of penetration structures 186 and the insulated wiring portion may be freely disposed. Accordingly, properties of the capacitor structure 18 and properties of the insulated wiring portion may be enhanced and thus performance of the semiconductor chip 2200 or the semiconductor device may be enhanced.

Each of the semiconductor chips 2200 may further include an input/output pad 2210 and an input/output connection wiring 4265 that is disposed at a lower portion of the input/output pad 2210. The input/output connection wiring 4265 may be electrically connected to a part of the second bonding structures 4250.

In an embodiment, in the semiconductor package 2003, a plurality of semiconductor chips 2200 may be electrically connected to each other by a connection structure 2400 having a bonding wire type. In an embodiment, in the semiconductor package 2003, a plurality of semiconductor chips 2200 may be electrically connected to each other by a connection structure including a through silicon via (TSV).

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

What is claimed is:

1. A semiconductor device, comprising:
a cell structure comprising a gate stacking structure in a first region and an insulation structure in a second region, the gate stacking structure comprising a plurality of gate electrodes while interposing an interlayer insulation layer therebetween;
a first wiring portion disposed on a first surface of the cell structure;
a second wiring portion disposed on a second surface of the cell structure opposite to the first surface;
a channel structure at least partially penetrating the gate stacking structure and being electrically coupled with the first wiring portion and the second wiring portion; and
a capacitor structure comprising a plurality of penetration structures, each of the plurality of penetration structures at least partially penetrating at least a portion of the insulation structure,
wherein a first one of the first wiring portion and the second wiring portion comprises a capacitor wiring comprising a first capacitor wiring and a second capacitor wiring spaced apart from each other,
wherein the plurality of penetration structures comprises a first penetration structure and a second penetration structure,
wherein the first penetration structure is electrically coupled with the first capacitor wiring and is electrically insulated from an insulated wiring portion,
wherein the insulated wiring portion is a second one of the first wiring portion and the second wiring portion, and
wherein the second penetration structure is electrically coupled with the second capacitor wiring and is electrically insulated from the insulated wiring portion.

2. The semiconductor device of claim 1, wherein the second penetration structure comprises a plurality of second penetration structures adjacent to the first penetration structure,
wherein the first penetration structure and the plurality of second penetration structures are electrically coupled with the capacitor wiring, and
wherein the first penetration structure and the plurality of second penetration structures are spaced apart from the insulated wiring portion and are insulated from the insulated wiring portion.

3. The semiconductor device of claim 1, further comprising:
an insulation portion comprising a first insulation portion between the cell structure and the first wiring portion, and a second insulation portion between the cell structure and the second wiring portion,
wherein each of the first penetration structure and the second penetration structure comprises a penetration body portion and a capacitor connecting portion,
wherein the penetration body portion at least partially penetrates the insulation structure and is spaced apart from the insulated wiring portion while interposing a first one of the first insulation portion and the second insulation portion therebetween, and
wherein the capacitor connecting portion at least partially penetrates at least a second one of the first insulation portion and the second insulation portion to electrically couple the penetration body portion and the capacitor wiring.

4. The semiconductor device of claim 3, wherein an end of the penetration body portion disposed at a side of the insulated wiring portion and spaced apart from the insulated wiring portion is an insulated end that is at least partially surrounded by the insulation portion.

5. The semiconductor device of claim 3, wherein the gate stacking structure comprises a plurality of gate stacking portions stacked in a thickness direction of the semiconductor device, and
wherein the penetration body portion comprises a plurality of body portions disposed to respectively correspond to the plurality of gate stacking portions.

6. The semiconductor device of claim 3, wherein the gate stacking structure comprises a plurality of gate stacking portions stacked in a thickness direction of the semiconductor device,
wherein the insulation structure comprises a plurality of insulation stacking portions disposed to respectively correspond to the plurality of gate stacking portions, and
wherein the penetration body portion comprises a plurality of body portions at least partially penetrating the plurality of insulation stacking portions, respectively.

7. The semiconductor device of claim 3, wherein, in a thickness direction of the semiconductor device, a length of the penetration body portion is greater than a separation distance between the penetration body portion and the insulated wiring portion.

8. The semiconductor device of claim 1, further comprising:
an insulation portion comprising a first insulation portion between the cell structure and the first wiring portion, and a second insulation portion between the cell structure and the second wiring portion,
wherein the channel structure comprises a channel body portion, a first channel connecting portion, and a second channel connecting portion,
wherein the channel body portion at least partially penetrates the gate stacking structure,
wherein the first channel connecting portion at least partially penetrates the first insulation portion to electrically couple the channel body portion and the first wiring portion,
wherein the second channel connecting portion at least partially penetrates the second insulation portion to electrically couple the channel body portion and the second wiring portion, and
wherein each of the plurality of penetration structures comprises one of a first capacitor connecting portion having a same structure as the first channel connecting portion and a second capacitor connecting portion having a same structure as the second channel connecting portion.

9. The semiconductor device of claim 1, wherein, in a plan view, at least one of the plurality of penetration structures is disposed not to overlap the insulated wiring portion, or
wherein, in the second region, a pitch of the plurality of penetration structures is different from a pitch of wiring portions comprised in the insulated wiring portion.

10. The semiconductor device of claim 1, wherein a thickness of a wiring layer comprised in the insulated wiring portion is greater than a thickness of a wiring layer of the capacitor wiring.

11. The semiconductor device of claim 1, wherein the first wiring portion comprises a bit line electrically coupled with the channel structure, and the capacitor wiring,
wherein the second wiring portion comprises a source wiring layer electrically coupled with the channel structure, and
wherein each of the plurality of penetration structures comprises:
a penetration body portion at least partially penetrating the insulation structure and being spaced apart from the second wiring portion; and
a first capacitor connecting portion electrically coupling the penetration body portion and the capacitor wiring.

12. The semiconductor device of claim 11, wherein, in the second region, a second wiring layer comprised in the second wiring portion comprises or is formed of a single portion, or
wherein, in the second region, a pitch of the plurality of penetration structures is less than a pitch of wiring portions comprised in the second wiring layer.

13. The semiconductor device of claim 1, wherein the first wiring portion comprises a bit line electrically coupled with the channel structure,
wherein the second wiring portion comprises a source wiring layer electrically coupled with the channel structure, and the capacitor wiring, and
wherein each of the plurality of penetration structures comprises:
a penetration body portion at least partially penetrating the insulation structure and being spaced apart from the first wiring portion; and
a second capacitor connecting portion electrically coupling the penetration body portion and the capacitor wiring.

14. The semiconductor device of claim 1, wherein, in a plan view, at least one of the first capacitor wiring or the second capacitor wiring comprises a plurality of extension portions extending to be parallel to each other, and
wherein at least one of the first penetration structure or the second penetration structure comprises a plurality of penetration sub-structures that are spaced apart from each other in each of the plurality of extension portions.

15. The semiconductor device of claim 1, wherein, in a plan view, at least one of the first capacitor wiring or the second capacitor wiring comprises a plurality of extension portions extending to be parallel to each other, and
wherein, in the plan view, at least one of the first penetration structure or the second penetration structure has an extended shape that longitudinally extends in each of the plurality of extension portions.

16. The semiconductor device of claim 1, wherein the semiconductor device is a bonding semiconductor device further comprising a circuit region bonded to a cell region.

17. A semiconductor device, comprising:
a cell structure comprising a gate stacking structure in a first region and an insulation structure in a second region, the gate stacking structure comprising a plurality of gate electrodes while interposing an interlayer insulation layer therebetween;
a first wiring portion disposed on a first surface of the cell structure;
a second wiring portion disposed on a second surface of the cell structure opposite to the first surface;
a channel structure at least partially penetrating the gate stacking structure and being electrically coupled with the first wiring portion and the second wiring portion; and
a plurality of penetration structures, each of the plurality of penetration structures at least partially penetrating at least a portion of the insulation structure,
wherein the plurality of penetration structures comprise a first penetration structure and a plurality of second penetration structures adjacent to the first penetration structure,
wherein the first penetration structure and the plurality of second penetration structures are electrically coupled with a first one of the first wiring portion and the second wiring portion, and
wherein the first penetration structure and the plurality of second penetration structures are insulated from a second one of the first wiring portion and the second wiring portion.

18. The semiconductor device of claim 17, wherein the first one of the first wiring portion and the second wiring portion comprises a first wiring and a second wiring that are spaced apart from each other in a plan view,
wherein the first penetration structure is electrically coupled with the first wiring, and
wherein the plurality of second penetration structures are electrically coupled with the second wiring.

19. The semiconductor device of claim 17, wherein, in a plan view, at least one of the plurality of penetration structures is disposed not to overlap the second one of the first wiring portion and the second wiring portion, or
wherein, in the second region, a pitch of the plurality of penetration structures is different from a pitch of wiring portions comprised in the second one of the first wiring portion and the second wiring portion.

20. An electronic system, comprising:
a main substrate;
a semiconductor device disposed on the main substrate; and
a controller disposed on the main substrate and electrically coupled with the semiconductor device,
wherein the semiconductor device comprises:
a cell structure comprising a gate stacking structure in a first region and an insulation structure in a second region, the gate stacking structure comprising a plurality of gate electrodes while interposing an interlayer insulation layer therebetween;
a first wiring portion disposed on a first surface of the cell structure;
a second wiring portion disposed on a second surface of the cell structure opposite to the first surface;
a channel structure at least partially penetrating the gate stacking structure and being electrically coupled with the first wiring portion and the second wiring portion; and
a capacitor structure comprising a plurality of penetration structures, each of the plurality of penetration structures at least partially penetrating at least a portion of the insulation structure,
wherein a first one of the first wiring portion and the second wiring portion comprises a capacitor wiring comprising a first capacitor wiring and a second capacitor wiring spaced apart from each other,
wherein the plurality of penetration structures comprises a first penetration structure and a second penetration structure,
wherein the first penetration structure is electrically coupled with the first capacitor wiring and is electrically insulated from an insulated wiring portion,
wherein the insulated wiring portion is a second one of the first wiring portion and the second wiring portion, and
wherein the second penetration structure is electrically coupled with the second capacitor wiring and is electrically insulated from the insulated wiring portion.
